(19) United States
(12) Patent Application Publication
(10) Pub. No.: US 2010/0248151 A1
(43) Pub. Date: Sep. 30, 2010

(54) METHOD OF MAKING A PRINTING PLATE

(75) Inventors: Tadabumi TOMITA, Shizuoka-ken (JP); Hiroshi TASHIRO, Shizuoka-ken (JP); Hisao YAMAMOTO, Shizuoka-ken (JP)

Correspondence Address: Solaris Intellectual Property Group, PLLC, 401 Holland Lane, Suite 407, Alexandria, VA, 22314, US

(73) Assignee: FUJIFILM CORPORATION, Tokyo (JP)

(21) Appl. No.: 12/731,160

(22) Filed: Mar. 25, 2010

(30) Foreign Application Priority Data
Mar. 30, 2009 (JP) 2009-082530

(51) Int. Cl. G03F 7/20

(52) U.S. Cl. 430/306

(57) ABSTRACT

A method of making a printing plate which has easy removability of engraving residue generated in laser engraving and has excellent reproducibility of thin lines is provided. The method includes in the following order: engraving by laser irradiation a relief forming layer of a printing plate precursor, the relief forming layer including a binder polymer having a glass transition temperature (Tg) of 20° C. or higher; and treating a surface of the engraved relief forming layer with an emulsion cleaner.

### CROSS-REFERENCE TO RELATED APPLICATION

This application claims priority under 35 USC 119 from Japanese Patent Application No. 2009-082530 filed on Mar. 30, 2009, the disclosure of which is incorporated by reference herein.

### BACKGROUND OF THE INVENTION

1. Field of the Invention

The present invention relates to a method of making a printing plate using laser engraving.

2. Description of the Related Art

As a method of forming recesses and projections on a photosensitive resin layer laminated on a support surface to form a printing plate, a method of exposing a relief forming layer formed using a photosensitive composition with ultraviolet light via an original image film to selectively cure an image area, and removing an uncured area with a developer, so-called “analog platemaking”, is well known.

A relief printing plate is a letterpress printing plate including a relief layer having recesses and projections, and such a relief layer having recesses and projections is obtained by patterning a relief forming layer containing, as a main component, a photosensitive composition containing an elastomeric polymer such as a synthetic rubber, a resin such as a thermoplastic resin, or a mixture of a resin and a plasticizer, to form recesses and projections. Among such relief printing plates, a printing plate having a soft relief layer is sometimes called a flexographic printing plate.

When a relief printing plate is made by analog platemaking, generally, since an original image film using a silver salt material is required, production time and costs for the original image film are necessary. Further, since chemical treatment is necessary for developing an original image film, and disposal of a development waste solution is also necessary, even simpler processes for producing a plate such as, for example, a method not using an original image film, and a method not requiring development treatment are being studied.

In recent years, a method of platemaking of a relief forming layer by scanning light exposure without using an original film is being studied.

For a procedure not requiring an original film, a relief printing plate precursor has been proposed in which a laser-sensitive mask layer element which can form an image mask is provided on a relief forming layer (see, for example, Japanese Patent No. 2773847 and Japanese Patent Application Laid-Open (JP-A) No. 9-171247). According to the process of platemaking using a plate precursor, since an image mask having the same function as that of an original image film is formed from the mask layer element by laser irradiation based on image data, the process is called a “mask CTP (Computer-To-Plate) method”. In this process, an original image film is not required, but platemaking treatment thereafter includes a step of performing light exposure with ultraviolet light via an image mask to develop and remove an uncured area, and there is room for improvement since development treatment is necessary.

As a method of manufacturing a plate without using a developing step, many so-called “direct engraving CTP methods” have been proposed in which a relief forming layer is directly engraved with a laser to manufacture a plate. The direct engraving CTP method is a method of forming recesses and projections, which are to be a relief, by engraving with a laser, and has an advantage in that, unlike a relief formation method using an original image film, a relief shape can be freely controlled. For this reason, when an image such as an outline character is formed, its region may be engraved deeper than other regions, or when a fine dot image is formed, engraving with a shoulder may be performed in view of resistance to a printing pressure.

A wide variety of printing materials used for the direct engraving CTP method have been proposed (see, for example, Japanese National Phase Publication No. 2007-537897 and Japanese Patent Application Laid-Open (JP-A) No. 2001-121833).

In the direct engraving CTP method, adhesive liquid substances are generated as engraving residue when a relief forming layer is subjected to plate making directly by laser. Since the engraving residue left on the surface of the plate seriously affects the printing quality, improved removability of the generated engraving residue is desired.

For the purpose of improving the removability of the engraving residue, a technique is specifically disclosed, for example in Japanese National Phase Publication No. 2007-537897, wherein, after a relief forming layer obtained by cross-linking a cross-linkable layer containing an elastomeric binder, a cross-linking agent (for example, ethylene unsaturated monomers), a suitable initiator, an absorbent for laser irradiation such as carbon black, and the like is engraved by laser, the relief forming layer is cleaned using a cleaner containing at least one component selected from the group consisting of lactones, carboxylate esters, and ether alcohols.

JP-A No. 2001-121833 discloses that, after a relief forming layer containing silicone rubber and carbon black is engraved by laser, the plate is cleaned using a solvent which does not dissolve or does not significantly swell the resultant relief layer.

However, the relief forming layers in the techniques described in Japanese National Phase Publication No. 2007-537897 and JP-A No. 2001-121833 do not have a high engraving sensitivity and have been unsuitable for forming (or reproducing) thin lines.

### SUMMARY OF THE INVENTION

The present invention is made in view of the above, and the object of the present invention is to provide a method of making a printing plate which has easy removability of engraving residue which is generated in laser engraving and has excellent reproducibility of thin lines.

According to an aspect of the invention, a method of making a printing plate includes in the following order:

engraving by laser irradiation a relief forming layer of a printing plate precursor, the relief forming layer including a binder polymer having a glass transition temperature (Tg) of 20° C. or higher; and

treating a surface of the engraved relief forming layer with an emulsion cleaner.

### BRIEF DESCRIPTION OF THE DRAWINGS

FIG. 1 is a schematic constitution view (perspective view) illustrating a plate-making apparatus having a fiber-coupled semiconductor laser recording apparatus applicable to the present invention.

### DETAILED DESCRIPTION OF THE INVENTION

Hereinbelow, the present invention is described in detail.

A method of making a printing plate of the present invention includes at least: engraving by laser irradiation a relief forming layer of a printing plate precursor, the relief forming layer including a binder polymer having a glass transition temperature (Tg) of 20° C. or more (step (1)); and treating a surface of the engraved relief forming layer with an emulsion cleaner (step (2)), in this order.

As used herein, in the description of a printing plate precursor and a printing plate, a flat-surface layer (i.e., layer having a flat surface) as an image forming layer to be subjected to laser engraving is referred to as “a relief forming layer”, and a layer having an uneven surface formed by laser engraving of the relief forming layer is referred to as “a relief layer”.

The method of making a printing plate of the present invention is applicable to methods of making a printing plate used in letterpress printing, planographic printing, intaglio printing, or mimeograph printing. Since a printing plate precursor of the present invention is suitable for embodiments where a part of the resin which constitutes the relief forming layer is removed by ablation by laser irradiation to form recesses and projections, the method of forming a printing plate of the present invention is preferably applied, among others, to a letterpress printing plate in which recesses and projections are formed to be an image, and particularly preferably to a flexographic printing plate which is a letterpress printing plate. As used herein, the term “flexographic printing plate” means a plate having at least a relief layer including a resin composition, on which relief layer concave portions and convex portions having differences in their heights of about 5 μm to 700 μm are formed so as to form an image pattern. A flexographic printing plate is a printing plate wherein inks on the convex portions are transferred directly or indirectly to a medium such as a printing paper sheet by allowing the inks to adhere selectively on the convex portions by utilizing the differences between the heights of the concave portions and the convex portions.

Hereinbelow, the step (1) and step (2) are described.

Step (1)

In the step (1), the relief forming layer of the printing plate precursor, the relief forming layer at least containing a binder polymer having a glass transition temperature of 20° C. or more, is engraved by laser irradiation.

Printing Plate Precursor

First, a printing plate precursor used in this step is described.

The printing plate precursor used in this step has at least a relief forming layer containing at least a binder polymer (A) having a glass transition temperature of 20° C. or more.

Binder Polymer (A) Having Glass Transition Temperature of 20° C. or More

In the present invention, “a binder polymer having a glass transition temperature of 20° C. or more” is not particularly limited as long as the glass transition temperature is within the range, and may be selected depending on a variety of characteristics such as, particularly, ease of laser engraving, ink receiving and transferring ability or engraving residue dispersibility.

For example, natural rubbers are not encompassed within the “binder polymer having a glass transition temperature of 20° C. or more” because the glass transition temperature of natural rubbers is generally lower than 20° C. and usually not higher than −40° C.

Hereinafter, in some cases, glass transition temperature is referred to as “Tg”, and the (A) binder polymer having a glass transition temperature of 20° C. or more is referred to as “(A) specific binder”.

Examples of preferable (A) specific binders include polystyrenes, polyesters, polyamides, polyureas, polyamide-imides, polyurethanes, polysulfones, polyether sulfones, polyimides, polycarbonates, hydrophilic polymers containing a hydroxyethylene unit, (meth)acrylic resins, acetal resins, epoxy resins, synthetic rubbers, and thermoplastic elastomers.

For example, in the viewpoint of laser engraving sensitivity, polymers including a partial structure which may be thermally decomposed by exposure to light or heating are preferred. Preferable examples of such polymers include those described in JP-A No. 2008-163081, paragraph [0038]. Further, in order, for example, to form a soft and flexible film, soft resins or thermoplastic elastomers are selected, and those described in detail in JP-A No. 2008-163081, paragraphs [0039] to [0040] are exemplified. Further, in the viewpoint of improving the ease of preparation of compositions for relief forming layers and improving the resistance of obtained printing plates to oil-based inks, hydrophilic polymers or alcoholphilic polymers are preferably employed. Examples of hydrophilic polymers include those described in detail in JP-A No. 2008-163081, paragraph [0041].

In order to cure the relief forming layer by heating and/or light exposure to improve the strength of the layer, polymers having a carbon-carbon unsaturated bond are preferably employed.

Examples of such polymers containing a carbon-carbon unsaturated bond in a main chain thereof include polystyrene-polybutadiene (SB), polystyrene-polybutadiene-polystyrene (SBS), polystyrene-polyisoprene-polystyrene (SIS), and polystyrene-polyethylene/polybutylene-polystyrene (SEBS).

Polymers having a carbon-carbon unsaturated bond in a side chain thereof may be obtained by introducing, as the side chain, a polymerizable group (group containing a carbon-carbon unsaturated bond) such as an allyl group, an acryloyl group, a methacryloyl group, a styryl group or a vinylether group into the backbone of each of the polymers described above as preferable (A) specific binders. As a method of introducing a carbon-carbon unsaturated bond in the side chain of the polymer, any of known methods may be employed such as (1) a method wherein the polymer is copolymerized with a structural unit having a polymerizable group precursor formed by binding a protecting group to a polymerizable group, and then a protecting group is eliminated to produce a polymerizable group, or (2) a method wherein macromolecular compounds having plural reactive groups such as hydroxyl group(s), amino group(s), epoxy group(s) and/or carboxyl group(s) are synthesized, and then carbon-carbon unsaturated bonds are introduced by a polymer reaction of compounds having groups which react with these reactive groups and having carbon-carbon unsaturated bonds with the macromolecular compounds. By these methods, the amount of introduced unsaturated bonds and polymerizable groups in the macromolecular compound may be controlled.

When water-based inks or UV monomer inks are used, in view of the requirement for some degree of hydrophilicity and in view of improved cleanability by an emulsion cleaner, a polymer having a hydroxyl group (—OH) is also preferably used as (A) a specific binder to be used in the present invention. The polymer backbone having a hydroxyl group (—OH) may be a (meth)acrylic resin, an epoxy resin, a hydrophilic polymer containing a hydroxyethylene unit, a polyvinyl acetal, a polyester, or a polyurethanes, but not particularly limited thereto.

As acrylic monomers used for synthesizing the (meth)acrylic resins having a hydroxyl group, (meth)acrylic acid esters, crotonic acid esters, (meth)acrylamides, each of which have a hydroxyl group in a molecule thereof, are preferred. Specific examples of such monomers include 2-hydroxyethyl (meth)acrylate, 2-hydroxypropyl (meth)acrylate, 4-hydroxybutyl (meth)acrylate.

Preferable examples of the (meth)acrylic resins having a hydroxyl group include copolymers obtained by polymerization of the monomers described above with known (meth)acryl monomers and/or vinyl monomers.

Preferable specific examples of the epoxy resins having a hydroxyl groups in a side chain thereof, include epoxy resins obtained by polymerizing addition products of bisphenol A and epichlorohydrin as a starting monomer.

As the polyesters having a hydroxyl group, polymers composed of hydroxycarboxylic acid units such as polylactic acid units are preferably employed. Specific examples of such polyesters are preferably selected from the group consisting of polyhydroxyalkanoate (PHA), lactic acid polymers, polyglycolic acid (PGA), polycaprolactone (PCL), poly(butylenesuccinic acid), and derivatives or mixtures thereof.

Further, hydrophilic polymers containing a hydroxyethylene unit are also preferably employed. As the hydrophilic polymers containing a hydroxyethylene unit, at least one of polyvinyl alcohol (PVA) and derivatives thereof may preferably be employed.

Examples of PVA derivatives include acid modified PVAs which are obtained by modifying at least a part of hydroxyl groups of the hydroxyethylene unit into acid radicals such as carboxyl groups, modified PVAs which are obtained by modifying a part of hydroxyl groups of the hydroxyethylene unit into (meth)acryloyl groups, modified PVAs which are obtained by modifying at least a part of hydroxyl groups of the hydroxyethylene unit into amino groups, modified PVAs which are obtained by introducing ethylene glycol, propylene glycol or multimers thereof into at least a part of hydroxyl groups of the hydroxyethylene unit, and polyvinyl acetals obtained by treating polyvinyl alcohols with aldehydes. Among these, polyvinyl acetals are particularly preferably employed. Aldehydes used for acetal treatment may be acetaldehyde or butylaldehyde because of the ease of handling. Polyvinyl butyral is particularly preferably employed as a PVA derivative.

Other known PVA derivatives such as polymers obtained by esterifying polyvinyl alcohol with cinnamic acid and succinic acid (see, for example, U.S. Pat. No. 2,861,058), polymers obtained by esterifying partially-saponified polyvinyl acetate with azidephthalic anhydride (see, for example, U.S. Pat. No. 3,096,311), as well as polymers obtained by introducing a phenolic hydroxyl group together with a photosensitive group into a side chain of PVA (Japanese Patent Publication (JP-B) No. 49-44601) or PVA derivatives obtained by introducing a cinnamate group and a sulfo (or salts thereof) alkyl group or a sulfo (or salts thereof) alkenyl group into completely-saponified or partially-saponified polyvinyl alcohol (see, for example, JP-A No. 48-55282) may also be employed.

Thus, specific binders (A) in the relief forming layer may be selected depending on the object, while taking the physical properties of the printing plate according to applications into consideration, and one specific binder may be used alone or two or more specific binders may be used in combination.

The weight-average molecular weight (in terms of polystyrene measured by GPC) of a specific binder (A) used in the present invention is preferably 5,000 to 500,000. When the weight-average molecular weight of the binder is 5,000 or more, the morphological stability of the resin per se is excellent, and when the weight-average molecular weight of the binder is 500,000 or less, a relief forming layer is advantageously prepared because the binder dissolves easily in a solvent such as water. The weight-average molecular weight of the binder polymer is preferably 10,000 to 400,000, and particularly preferably 15,000 to 300,000.

Regarding values of the glass transition temperatures (Tg) of polymers (high molecular compounds), the Tgs of 700 types of polymers are described in “Polymer Data Handbook, The Society of Polymer Science, Japan eds., published by BAIFUKAN CO., LTD, January, 1986, p. 526-541”. For example, the glass transition temperatures of polystyrene (Tg=90° C. to 100° C.), (meth)acrylic resin (Tg=45° C.), rigid polyvinyl chloride (Tg=87° C.), nylon 66 (Tg=47° C.), polyester (PET) (Tg=81° C.), PVA (Tg=85° C.), PVB (Tg=68° C.), cellulose (room temperature to 160° C.) and the like are described. Polymers described in this literature having glass transition temperatures of more than 20° C. like the polymers described above may be employed as specific binders (A) of the present invention.

The glass transition temperature (Tg) of a specific binder (A) of the present invention is required to be 20° C. or more, preferably 25° C. or more, more preferably 40° C. or more, and most preferably 50° C. or more.

In the relief forming layer of the present invention, two or more binder polymers may be used in combination, and in this case, at least one type of the binder polymers is the binder polymer (the specific polymer (A)) having a Tg of 20° C. or more. In particular, when two or more types of binder polymers are used in the relief forming polymer of the present invention, the average of the Tgs of the binder polymers is preferably higher than 20° C., and it is more preferable that all of the binder polymers have Tgs of 20° C. or more. That is, all the binder polymers in the relief forming layer are preferably the specific binder (A).

In the cases where the binder polymers are cross-linked in the relief forming layer, when the Tg of the cross-linked polymer before laser engraving is 20° C. or more, the binder polymers is within the scope of the present invention. That is, the specific binder (A) of the present invention may be cross-linked.

The Tg of the polymer usually tends to be higher when the polymer is cross-linked. Therefore, when the Tg of the polymer is 20° C. or more before the polymer is cross-linked, it follows that the Tg of the polymer after being cross-linked is 20° C. or more.

The glass transition temperature (Tg) of the polymer may change due to addition of additives to the relief forming layer. Specifically, by adding complex compounds, inorganic fillers or the like, the glass transition temperature of polymers used in combination may be changed.

Specifically, for example, as a known plasticizer, a low molecular weight compound such as diethyl phthalate or dioctyl phthalate may be used in combination with the polymer to adjust the Tg of the polymer in such a manner that the Tg decreases.

Also, the Tg may be adjusted by a method in which block copolymers or graft copolymers are formed by copolymerizing two types of polymers, or by a polymer blend in which two or more types of polymers are mixed.

In these cases, when the polymers each have a glass transition temperature of 20° C. or higher, a relief forming layer of the present invention is formed.

After the Tg of the specific binder polymer of the present invention is adjusted by a method of addition of plasticizer or by a method of copolymerization, the Tg is preferably within the range of −15° C. to 80° C., more preferably −10° C. to 70° C., and most preferably −5° C. to 60° C. When the Tg falls within these ranges, an improved conformability to the surface having recesses and projections of the finally obtained relief layer and an improved shock-resistance of the finally obtained relief layer are obtained.

As a measurement method of the glass transition temperature (Tg) of the polymer, differential scanning calorimetry (DSC) is preferred, and commercially available apparatus DSC-60 (trade name, manufactured by Shimadzu Corporation) or the like may be used. The glass transition temperature of the polymer may be measured based on ISO 3146 (1985).

In the present invention, the value which was determined under the following conditions is used as the Tg: a value obtained by measuring in a temperature range from −100° C. to 150° C. at a heating rate of 10° C./min using differential scanning calorimetry DSC200 (trade name, manufactured by Seiko Instruments & Electronics Ltd.).

The total content of the binder polymer in the relief forming layer is preferably 15 to 75% by mass, and more preferably 20 to 65% by mass, with respect to the total mass of the solid content in the relief forming layer.

For example, when the content of the binder polymer in the relief forming layer of the present invention is 15% by mass or more, the obtained printing plate has a sufficient printing durability to be used as a printing plate. When the content of the binder polymer in the relief forming layer of the present invention is 75% by mass or less, other components are not insufficient, and even when a flexographic printing plate is employed as a printing plate, the obtained printing plate has a sufficient flexibility to be used for a printing plate.

When the specific binder (A) is used in combination with other binder polymers in the relief forming layer, the relief forming layer preferably contains 50% by mass or more, and more preferably 70% by mass or more of the specific binder (A), with respect to the total content of binder polymers contained in the relief forming layer.

(B) Photothermal Converting Agent

The relief forming layer of the present invention further contains a photothermal converting agent (B).

Photothermal converting agents are considered to accelerate thermal decomposition of the relief forming layer by absorbing laser beam to generate heat. Therefore, a photothermal converting agent which absorbs a laser beam having a wavelength used for engraving is preferably selected.

For example, in the step (2) of the present invention, when a laser which generates an infrared ray having a wavelength of 700 nm to 1300 nm (e.g., YAG laser, semiconductor laser, fiber laser, surface emitting laser) is used as a light source for laser engraving, the relief forming layer preferably contains a photothermal converting agent which can absorb a light having a wavelength of 700 nm to 1300 nm.

As a photothermal converting agent of the present invention, a variety of dyes and pigments are used.

Among the photothermal converting agents, the dyes may be commercially available dyes and known dyes such as those described in “Senryo Binran” (edited by The Society of Synthetic Organic Chemistry, Japan, 1970). Specific examples of the dyes include dyes having the maximum absorption wavelength within 700 nm to 1300 nm, such as azo dyes, metallic complex salt azo dyes, pyrazolone azo dyes, naphthoquinone dyes, anthraquinone dyes, phthalocyanine dyes, carbonium dyes, diimmonium compounds, quinone imine dyes, methine dyes, cyanine dyes, squarylium dyes, pyrylium salts, and metal thiolate complexes. Cyanine dyes such as heptamethine cyanine dyes, oxonol dyes such as pentamethine oxonol dyes, and phthalocyanine dyes are particularly preferably employed. For example, the dyes as those described in JP-A No. 2008-63554, paragraph [0124] to [0137] are exemplified.

Examples of the pigments to be used as the photothermal converting agents include commercially available pigments and pigments as those described in Color Index Handbook, “Advanced Pigment Handbook” (Japan Society of Colour Material eds., 1977), “Current Pigment Application Technology” (CMC Publishing Co., Ltd., 1986), and “Printing Ink Technology” (CMC Publishing Co., Ltd., 1984).

Examples of the types of the pigments include black pigments, yellow pigments, orange pigments, brown pigments, red pigments, violet pigments, blue pigments, green pigments, fluorescent pigments, metal powder pigments, and polymer-bound pigments. Specific examples of the pigments include insoluble azo pigments, azo lake pigments, condensed azo pigments, chelate azo pigments, phthalocyanine pigments, anthraquinone pigments, perylene pigments, perinone pigments, thioindigo pigments, quinacridone pigments, dioxazine pigments, isoindolinone pigments, quinophthalone pigments, dyeing lake pigments, azine pigments, nitroso pigments, nitro pigments, natural pigments, fluorescent pigments, inorganic pigments and carbon blacks. Among these pigments, carbon black is preferably employed because an effective photothermal conversion is attained due to high photothermal conversion coefficient; precipitations hardly occur while mixing due to closeness of the specific gravity to that of resin compound; a variety of grain size of carbon blacks and surface modified carbon blacks are commercially available and carbon black has good variety; and carbon black is broadly distributed as a raw material and cheap, and easy to be obtained.

Carbon black may be freely selected from those compliant with ASTM and various products for coloring, rubbers, dry batteries, and other applications, as long as it exhibits stable dispersibility in the composition. Examples of carbon blacks include furnace black, thermal black, channel black, lampblack and acetylene black.

Black colorants such as carbon black may be used as a color chip or a color paste, in which color chip or color paste carbon black is dispersed in advance in nitrocellulose or a binder by using as required a dispersant to facilitate the dispersion. Such chips and pastes are easily commercially available.

In the present invention, a carbon black having a relatively low specific surface area and a relatively low DBP absorption and a finely grained carbon black having a relatively large specific surface area may also be employed. Examples of suitable carbon black include PRINTEX (registered trademark) U, PRINTEX (registered trademark) A, or SPEZIALSCHWARz (registered trademark) 4 (manufactured by Degussa).

As a carbon black applicable to the present invention, a conductive carbon black having a specific surface area of at least 150 m²/g and a DBP number of at least 150 ml/100 g, from the viewpoint of improving the engraving sensitivity by effectively transmitting the heat generated by photothermal conversion to the polymer or the like around the carbon black.

The specific surface area is preferably at least 250 m²/g, and particularly preferably at least 500 m²/g. The DBP number is preferably at least 200 ml/100 g, and particularly preferably at least 250 ml/100 g. The carbon blacks mentioned above may be acidic or basic carbon black. Preferable carbon black is basic carbon black. A mixture of different binders may also be used.

Suitable conductive carbon blacks having a specific surface area of up to about 1500 m²/g and a DBP number of up to about 550 ml/100 g are commercially available as under the name of, for example, KETJENBLACK (registered trademark, registered trademark) EC300J, KETJENBLACK (registered trademark) EC600J (produced by Akzo), PRINTEX (registered trademark) XE (produced by Degussa) or BLACK PEARLS (registered trademark, registered trademark) 2000 (produced by Cabot), and KETJENBLACK (produced by Lion Corporation).

The content of the photothermal converting agent in the relief forming layer of the present invention is preferably within the range of 0.01 to 20% by mass, more preferably 0.05 to 10% by mass, and particularly preferably 0.1 to 5% by mass, with respect to the total mass of the solid content in the relief forming layer, although it varies depending on the molecular extinction coefficient intrinsic to the molecule thereof.

(C) Cross-Linking Agent

The relief forming layer of the present invention preferably further contains a cross-linking agent (C).

When containing the cross-linking agent (C), the relief forming layer can form a cross-linking structure therein.

Any cross-linking agent (C) may be employed for the present invention without particular limitation as long as the agent can form a macromolecule by a chemical reaction due to light or heat and cure the relief forming layer.

In particular, the cross-linking agent (C) may preferably a polymerizable compound having an ethylenically unsaturated double bond (hereinafter also referred to as “polymerizable compound”), a silane coupling agent or the like. Any of these compounds may form a relief forming layer by reacting with the specific binder (A), or molecules of any of these compounds may react with each other to form a relief forming layer. Alternatively, a relief forming layer may be formed by both of these reactions.

When the cross-linking agent (C) reacts with the specific binder (A), a silane coupling agent is preferably used as the cross-linking agent (C). When the molecules of the cross-linking agent (C) react with each other, a polymerizable compound is preferably used as the cross-linking agent (C); in this embodiment, a thermal polymerization initiator (D) may also be preferably used in combination with the cross-linking agent. A polymerizable compound and a silane coupling agent in combination may be used as the cross-linking agent (C).

Polymerizable Compound

A polymerizable compound used as the cross-linking agent (C) is selected arbitrarily from among compounds having at least 1, preferably 2, and more preferably 2 to 6 ethylenically unsaturated double bonds.

Monofunctional monomers which have one ethylenically unsaturated double bond therein and polyfunctional monomers which have 2 or more ethylenically unsaturated double bonds therein, which are employed as polymerizable compounds will now be described.

Examples of the monofunctional monomers and polyfunctional monomers include esters of an unsaturated carboxylic acid (e.g., acrylic acid, methacrylic acid, itaconic acid, crotonic acid, isocrotonic acid, maleic acid) and a polyol compound, and amides of an unsaturated carboxylic acid and a polyamine compound.

In the formation of a relief forming layer of the present invention, a polyfunctional monomer is preferably employed from the viewpoint that a crosslinked structure be easily formed. The molecular weight of such polyfunctional monomers is preferably 200 to 2,000.

In the present invention, a compound having a sulfur atom therein is preferably employed as the polymerizable compound from the viewpoint of improving the engraving sensitivity.

As such polymerizable compounds having a sulfur atom therein, a polymerizable compound having 2 or more ethylenically unsaturated bonds and having a carbon-sulfur bond in a moiety that links 2 ethylenically unsaturated bonds among these bonds (hereinafter appropriately referred to as “sulfur-containing polyfunctional monomer”) is preferably employed from the viewpoint of improving the engraving sensitivity.

A functional group having a carbon-sulfur bond in a sulfur-containing polyfunctional monomer of the present invention may be a functional group having sulfide, disulfide, sulfoxide, sulfonyl, sulfonamide, thiocarbonyl, thiocarboxylic acid, dithiocarboxylic acid, sulfamic acid, thioamide, thiocarbamate, dithiocarbamate, or thiourea.

A linking group having a carbon-sulfur bond, which links 2 ethylenically unsaturated bonds in a sulfur-containing polyfunctional monomer is preferably at least one unit selected from the group consisting of —C—S—, —C—SS—, —NH(C═S)O—, —NH(C═O)S—, —NH(C═S)S—, and —C—SO₂—.

The number of sulfur atoms contained in the sulfur-containing polyfunctional monomer is not particularly limited as long as it is 1 or more, and may be selected appropriately depending on the object. The number is preferably 1 to 10, more preferably 1 to 5 and still more preferably 1 to 2, from the viewpoint of the balance between the engraving sensitivity and the solubility to a coating solvent.

On the other hand, the number of ethylenically unsaturated moieties contained in the molecule is not particularly limited as long as it is 2 or more, and may be selected appropriately depending on the object. The number is preferably 2 to 10, more preferably 2 to 6, and more preferably 2 to 4, from the viewpoint of flexibility of a cross-linking film.

The molecular weight of the sulfur-containing polyfunctional monomer used in the present invention is preferably 120 to 3,000, and more preferably 120 to 1,500 from the viewpoint of the flexibility of a film to be formed.

A sulfur-containing polyfunctional monomer of the present invention may be used individually, or may be used as a mixture with a polyfunctional polymerizable compound or monofunctional polymerizable compound which has no sulfur atoms therein.

From the viewpoint of the engraving sensitivity, it is preferable to use the sulfur-containing polyfunctional monomer individually or a mixture of the sulfur-containing polyfunctional monomer and a monofunctional ethylenic monomer, and more preferable to use a mixture of the sulfur-containing polyfunctional monomer and a monofunctional ethylenic monomer.

Physical properties of the film such as brittleness or flexibility of a relief forming layer of the present invention also may be adjusted by using polymerizable compounds including the sulfur-containing polyfunctional monomer.

The total content of polymerizable compounds including a sulfur-containing polyfunctional monomer in the relief forming layer is 10 to 60% by mass, and more preferably 15 to 45% by mass, with respect to the nonvolatile components from the viewpoint of flexibility or brittleness of the cross-linking film.

When the sulfur-containing polyfunctional monomer and another polymerizable compound are used in combination, the amount of the sulfur-containing polyfunctional monomer in the polymerizable compounds in total is preferably 5% by mass, and more preferably 10% by mass.

When the polymerizable compound is used as the cross-linking agent (C), the polymerizable compound is preferably used in a combination with a photopolymerization initiator or thermal polymerization initiator.

Particularly, the combination with a thermal polymerization initiator is preferred from the viewpoint of improving the degree of cross-linking. The quality of engraving may be improved by improving the degree of cross-linking

The polymerization initiator will be described later.

Silane Coupling Agent

In the present invention, a silane coupling agent may be used as the cross-linking agent (C).

In the present invention, a functional group which has at least one of an alkoxy group or a halogen group bound directly to a silicon atom is referred to as a silane coupling group. A compound having at least one silane coupling group is referred to as a silane coupling agent. A silane coupling group preferably has 2 or more, and particularly preferably 3 or more groups selected from the group consisting of an alkoxy group and a halogen group, each of which directly binds to a silicon atom.

It is essential that, as mentioned above, the silane coupling agent of the present invention have at least one of an alkoxy group and a halogen group as the functional group directly bound to a silicon atom. A silane coupling agent having an alkoxy group is preferred from the viewpoint of ease of handling of the compound.

As the alkoxy group, an alkoxy group having 1 to 30 carbon atoms is preferred from the viewpoint of the removability and printing durability of liquid debris. An alkoxy group having 1 to 15 carbon atoms is more preferred, and an alkoxy group having 1 to 5 carbon atoms is particularly preferred.

Examples of the halogen atom include fluorine, chlorine, bromine, and iodine. Chlorine and bromine are preferred from the viewpoint of ease of synthesis and stability, and chlorine is more preferred.

The silane coupling agent of the present invention preferably has 1 to 10, more preferably 1 to 5, and particularly preferably 2 to 4 silane coupling groups mentioned above, from the viewpoint of maintaining a good balance between the degree of cross-linking and the flexibility of a film.

When the silane coupling agent has 2 or more silane coupling groups, the silane coupling groups are preferably linked via a linking group. Examples of the linking group include divalent or higher-valent organic groups which may have a substituent such as a hetero atom or a hydrocarbon. From the viewpoint of high engraving sensitivity, the linking group preferably contains a hetero atom (such as N, S, or O), and particularly preferably contains a sulfur atom.

From this point of view, the silane coupling agent used in the present invention is preferably a compound which has 2 silane coupling groups in which an alkoxy group such as a methoxy group or an ethoxy group, especially a methoxy group, is bound to a silicon atom, and in which these silane coupling groups are bound in the compound via an alkylene group containing a hetero atom, particularly preferably a sulfur atom.

Specific examples of silane coupling agents applicable to the present invention include vinyltrichlorosilane, vinyltrimethoxysilane, vinyltriethoxysilane, β-(3,4-epoxycyclohexyl)ethyltrimethoxysilane, γ-glycidoxypropyltrimethoxysilane, γ-glycidoxypropylmethyldiethoxysilane, γ-glycidoxypropyltriethoxysilane, γ-methacryloxypropylmethyldimethoxysilane, γ-methacryloxypropyltrimethoxysilane, γ-methacryloxypropylmethyldiethoxysilane, γ-methacryloxypropyltriethoxysilane, γ-acryloxypropyltrimethoxysilane, N-(β-aminoethyl)-γ-aminopropylmethyldimethoxysilane, N-(β-aminoethyl)-γ-aminopropyltrimethoxysilane, N-(β-aminoethyl)-γ-aminopropyltriethoxysilane, γ-aminopropyltrimethoxysilane, γ-aminopropyltriethoxysilane, N-phenyl-γ-aminopropyltrimethoxysilane, γ-mercaptopropyltrimethoxysilane, γ-chloropropyltrimethoxysilane, and γ-ureidopropyltriethoxysilane.

A silane coupling agent in a relief forming layer of the present invention may be used individually, or 2 or more types of silane coupling agents may be used in combination.

The content of silane coupling agent contained in a relief forming layer of the present invention is preferably 0.1 to 80%, more preferably 1 to 40% and most preferably 5 to 30% by mass, in terms of solid content.

In a relief forming layer of the present invention, when a polymer having a hydroxyl group is used as the specific binder (A), the silane coupling group in the silane coupling agent may undergo an alcohol exchange reaction with the hydroxyl group (—OH) in the binder polymer to form a crosslinked structure. As a result, the molecules of the binder polymer are three-dimensionally cross-linked via the silane coupling agent.

In order to enhance the formation of crosslinked structure between the silane coupling agent and the polymer having a hydroxyl group, the relief forming layer of the present invention preferably further contains an alcohol exchange reaction catalyst.

Any alcohol exchange reaction catalyst may be employed without limitation as long as the catalyst is a reaction catalyst generally used in a silane coupling reaction.

Hereinbelow, acid or base catalysts (C-1) and metal complex catalysts (C-2), which are representative alcohol exchange reaction catalysts, will be described sequentially.

Acid or Base Catalyst (C-1)

The catalyst to be used may be an acid or base compound without modification, or an acid or base compound dissolved in a solvent such as water, an organic solvent or the like (hereinafter, referred to as acid catalyst and acid catalyst, respectively). A concentration of the catalyst when dissolved in the solvent is not particularly limited, and may be selected depending on the characteristics of the acid or base compound used, desired content of the catalyst, or the like.

Examples of the acid catalyst and base catalyst are not particularly limited, and specifically include: acid catalysts such as hydrogenated halides such as hydrochloric acid, nitric acid, sulfuric acid, sulfurous acid, hydrogen sulfide, perchloric acid, hydrogen peroxide, carbonic acid, carboxylic acid such as formic acid or acetic acid, substituted carboxylic acid in which R in the structural formula represented by RCOOH is substituted by another element or a substituent, sulfonic acid such as benzenesulfonic acid, and phosphoric acid; and base catalysts such as ammonium bases such as aqueous ammonia, and amines such as ethylamine or aniline. From the viewpoint of rapidly proceeding the alcohol exchange reaction in the relief forming layer, methanesulfonic acid, p-toluenesulfonic acid, pyridinium p-toluene sulfonate, phosphoric acid, phosphonic acid or acetic acid is preferably used, and methanesulfonic acid, p-toluenesulfonic acid or phosphoric acid is particularly preferably used.

Metal Complex Catalyst (C-2)

The metal complex catalyst (C-2) used as the alcohol exchange reaction catalyst in the present invention preferably contains a metallic element selected from 2, 13, 4, and 5 Group in the periodic table, and an oxo compound or a hydroxy compound selected from the group consisting of β-diketone (such as acetylacetone), ketoester, hydroxycarboxylic acid or esters thereof, amino alcohol and enolic active hydrogen compound.

Among the metallic compounds which may constitute the catalyst, elements of Group 2A such as Mg, Ca, St, or Ba, elements of group 3B such as Al or Ga, elements of group 4A such as Ti or Zr and elements of group 5A such as V, Nb or Ta are preferred, and each of them forms a complex having high catalytic effects. Among these, complexes obtained using Zr, Al, or Ti (e.g., ethyl orthotitanate) are excellent and preferred.

These complexes have high stability in a water-based coating-liquid and have a good gelation-enhancing effect in a sol-gel reaction during heating and drying, and ethylacetoacetate aluminum diisopropylate, aluminum tris(ethylacetoacetate), di(acetylacetonate)titanium complex salt and zirconium tris(ethylacetoacetate) are particularly preferred.

Only one type of alcohol exchange reaction catalyst may be used in a relief forming layer of the present invention, or 2 or more types of alcohol exchange reaction catalyst may be used.

The content of alcohol exchange reaction catalyst in a relief forming layer of the present invention is preferably 0.01 to 20% by mass, more preferably 0.1 to 10% by mass, with respect to the specific binder (A) having a hydroxyl group.

(D) Polymerization Initiator

The relief forming layer of the present invention preferably further contains a polymerization initiator (D).

Any of polymerization initiators known to those skilled in the art may be employed without limitation. The polymerization initiators can be roughly classified into photopolymerization initiators and thermal polymerization initiators. In the present invention, thermal polymerization initiators are preferably employed from the viewpoint of improving the degree of cross-linking.

In the following, a radical polymerization initiator which is a preferable polymerization initiator will be described in detail, but the present invention is not limited thereto.

In the present invention, examples of preferable radical polymerization initiators include (a) aromatic ketones, (b) onium salt compounds, (c) organic peroxides, (d) thio compound, (e) hexaarylbiimidazole compounds, (f) ketoxime ester compounds, (g) borate compounds, (h) azinium compounds, (i) metallocene compounds, (j) active ester compounds, (k) compounds having a carbon-halogen bond, (l) azo compounds, but not limited thereto.

In the present invention, (c) organic peroxides and (l) azo compounds are more preferred, and (c) organic peroxides are particularly preferred, from the viewpoint of engraving sensitivity and the viewpoint that a good relief edge shape is obtained when such compound are used in the relief forming layer.

The following compounds are particularly preferred.

(C) Organic Peroxide

Examples of the (C) organic peroxides suitable for radical polymerization initiators which may be employed in the present invention include peroxyesters such as 3,3′4,4′-tetra-(tertiarybutylperoxycarbonyl)benzophenone, 3,3′4,4′-tetra-(tertiaryamylperoxycarbonyl)benzophenone, 3,3′4,4′-tetra-(tertiaryhexylperoxycarbonyl)benzophenone, 3,3′4,4′-tetra-(tertiaryoctylperoxycarbonyl)benzophenone, 3,3′4,4′-tetra-(cumylperoxycarbonyl)benzophenone, 3,3′4,4′-tetra-(p-isopropylcumylperoxycarbonyl)benzophenone, and di-tertiarybutyldiperoxyisophthalate.

(1) Azo Compound

Examples of the (1) azo compounds suitable for radical polymerization initiators which may be employed in the present invention include 2,2′-azobisisobutyronitrile, 2,2′-azobispropionitrile, 1,1′-azobis(cyclohexane-1-carbonitrile), 2,2′-azobis(2-methyl butyronitrile), 2,2′-azobis(2,4-dimethylvaleronitrile), 2,2′-azobis(4-methoxy-2,4-dimethylvaleronitrile), 4,4′-azobis(4-cyanovaleric acid), dimethyl 2,2′-azobisisobutyric acid, 2,2′-azobis(2-methylpropionamide oxime), 2,2′-azobis[2-(2-imidazolin-2-yl)propane], 2,2′-azobis{2-methyl-N-[1,1-bis(hydroxymethyl)-2-hydroxyethyl]propionamide}, 2,2′-azobis[2-methyl-N-(2-hydroxyethyl)propionamide], 2,2′-azobis(N-butyl-2-methylpropionamide), 2,2′-azobis(N-cyclohexyl-2-methylpropionamide), 2,2′-azobis[N-(2-propenyl)-2-methylpropionamide], and 2,2′-azobis(2,4,4-trimethylpentane).

As the above-described (a) aromatic ketones, (b) onium salt compounds, (d) thio compounds, (e) hexaarylbiimidazole compounds, (f) ketoxime ester compounds, (g) borate compounds, (h) azinium compounds, (i) metallocene compounds, (j) active ester compounds, and (k) compounds having a carbon-halogen bond, the compounds as those described in JP-A No. 2008-63554, paragraph [0074] to [0118] may be preferably employed.

The polymerization initiator may be used individually, or 2 or more types of the polymerization initiators may be used in combination.

The polymerization initiator may be added in an amount of 0.01 to 10% by mass, and more preferably 0.1 to 3% by mass, with respect to the total mass of the solid content of the relief forming layer.

Additional Additives

The relief forming layer of the present invention preferably further contains a plasticizer. It is required that plasticizers have an effect of softening the film formed from the relief forming layer for laser engraving, and have a good compatibility with the binder polymer.

Preferable examples of the plasticizers include dioctylphthalate, didodecylphthalate, polyethylene glycols, polypropylene glycol (monool type and diol type), and polypropylene glycol (monool type and diol type).

To a relief forming layer of the present invention, nitrocellulose or high thermal conductivity material is preferably added as an additive which improves the engraving sensitivity of the relief forming layer. Nitrocellulose, which is a self-reactive compound, generates heat by itself during laser engraving to assist thermal decomposition of the specific binder (A) coexisting therewith. As a result, the engraving sensitivity of the relief forming layer is improved. A high thermal conductivity material is added for the purpose of aiding heat transfer. Examples of the high thermal conductivity material include inorganic compounds such as metallic particles and organic compounds such as conductive polymers. The metallic particles are preferably gold particles, silver particles or copper particles, which have a diameter of the order of several nanometers to the order of micrometers. As the conductive polymers, conjugate polymers are particularly preferred. Specific examples of the conductive polymers include polyaniline and polythiophene.

By using a cosensitizer, the sensitivity for photocuring the relief forming layer of the present invention may be further improved.

Further, a small amount of the thermal polymerization inhibitor may be added in order to inhibit undesirable thermal polymerization of the polymerizable compound during the production of a relief forming layer or during the storage of the relief forming layer.

To the relief forming layer of the present invention, a colorant such as a dye or a pigment may be added for the purpose of coloring the relief forming layer of the present invention. By adding the colorant, performances of the obtained printing plate such as an enhancement of the visibility of an image portion or an adaptability to an image density measuring device may be improved.

Further, known additives such as fillers may be added in order to improve the physical properties of a cured film of the relief forming layer.

Preparation of Printing Plate Precursor

The printing plate precursor in the present invention includes a relief forming layer containing the components mentioned above. The relief forming layer is preferably provided on a support.

The printing plate precursor may further include, as required, an adhesive layer provided between the support and the relief forming layer, or a release layer or a protective film on the relief forming layer.

Relief Forming Layer

The relief forming layer is a layer containing at least the components described above, and is preferably a layer which is cured by at least one of light and heat, that is, a layer which has a cross-linking capability.

In an embodiment, a method of preparing a printing plate of the present invention preferably includes crosslinking a relief forming layer, and then subjecting it to laser engraving to form a relief layer. By cross-linking the relief forming layer, the abrasion of the relief layer during printing may be prevented, and a printing plate having a relief layer sharply engraved by laser engraving may be obtained.

The relief forming layer may be formed by molding a coating liquid for a relief forming layer, which contains the above-mentioned components, into the form of a sheet or a sleeve.

The relief forming layer is usually provided on the support which will be described later. The relief forming layer may also be formed directly on the surface of members such as a cylinder provided in an apparatus for plate making or printing, or may be placed to be fixed thereon. Therefore, the support is not always necessary because the back side of a cured relief forming layer (relief forming layer) of a printing plate precursor made by applying a relief forming layer of the present invention and by thermally cross-linking the relief forming layer from the back side (the opposite side of the surface on which a laser engraving is performed; the same is applied to a case where the relief forming layer has a cylindrical shape) serves as a support.

Support

A support which may be used for the printing plate precursor will now be described.

Although materials used for the support of a printing plate precursor is not limited, materials which have good size stability are preferably employed. Examples of the materials include metals such as steel, stainless, or aluminum; plastic resins such as polyesters (e.g., PET, PBT, PAN), or polyvinyl chloride; synthetic rubbers such as styrene-butadiene rubber; and plastic resins (e.g., epoxy resins, phenol resins) reinforced by glass fibers. Preferable examples of the support include polyethylene terephthalate (PET) films and steel substrates.

The shape of the support is determined depending on whether the relief forming layer has a sheet shape or a sleeve shape.

Adhesive Layer

An adhesive layer may be provided between a relief forming layer and a support for the purpose of reinforcing the adhesive strength between the relief forming layer and the support.

Examples of materials (adhesives) which may be used for the adhesive layer include those as described in “Handbook of Adhesives”, edited by I. Skeist, 2nd Edition, 1977.

Protective Film and Slip Coat Film

A protective film may be provided on the surface of the relief forming layer for the purpose of preventing scratches or hollows on the surface of the relief forming layer.

The thickness of the protective film is preferably 25 μm to 500 μm, and more preferably 50 μm to 200 μm. Examples of the protective film include polyester films such as those formed from polyethylene terephthalate (PET) and polyolefin films such as those formed from polyethylene (PE) or polypropylene (PP). The surface of the film may be matte. The protective film is required to be removable when the protective film is provided on the relief forming layer.

When the protective film is not removable or, on the contrary, is hardly adheres to the relief forming layer, a slip coat layer may be provided between the protective film and the relief forming layer. The slip coat layer preferably includes, as main ingredients, resins which can be dissolved in water or dispersed in water and which have a low adhesiveness, such as polyvinyl alcohols, polyvinyl acetates, partially-saponified polyvinyl alcohols, hydroxyalkyl cellulose, alkyl celluloses or polyamide resins.

Method of Making Printing Plate Precursor

Next, a method of making a printing plate precursor used in the present invention will now be described.

The method of forming a relief forming layer of the printing plate precursor used in the present invention is not particularly limited. For example, the relief forming layer may be formed in such a manner that a coating liquid for a relief forming layer, which contains the respective components described above, is prepared, the solvent is then removed from the coating liquid for a relief forming layer, and the liquid is then melt-extruded on a support. Alternatively, the relief forming layer may be formed by a method in which a coating liquid for a relief forming layer is casted on a support, and the support is dried in an oven to remove the solvent from the coating liquid.

Thereafter, a protective film may be laminated on the relief forming layer as required. Lamination may be performed by compressing a protective film and a relief forming layer, for example, using a heated calender roll, or may be performed by allowing the protective film to closely adhere to a relief forming layer on the surface of which a small amount of solvent is impregnated.

When a protective film is employed, first, a relief forming layer may be laminated on the protective film, and then a support is laminated thereon.

When an adhesive layer is to be provided, a support coated with an adhesive layer may be used. When a slip coat layer is to be provided, a protective film coated with a slip coat layer may be used.

The coating liquid for a relief forming layer may be prepared by dissolving a binder polymer including the specific binder (A), and as optional components, the photothermal converting agent (B) and/or a plasticizer in a suitable solvent, and, when a polymerizable compound is used as the cross-linking agent (C), then dissolving the polymerizable compound and the polymerization initiator (D). When a silane coupling agent is used as the (C) cross-linking agent, it is preferable that the silane coupling agent dissolved in the coating liquid for a relief forming layer in the final stage of the preparation. Since much of the solvent needs to be removed at the step of making a printing plate precursor, it is preferred that the solvent be a highly-volatile low molecular weight alcohol (e.g., methanol, ethanol, n-propanol, isopropanol, propylene glycol monomethyl ether), and the total amount of the solvent to be added be minimized by, for example, adjusting the temperature or the like.

The thickness of the relief forming layer of the printing plate precursor is preferably 0.05 mm to 10 mm, more preferably 0.05 mm to 7 mm, and particularly preferably 0.05 mm to 3 mm before and after cross-linking

Cross-linking of Relief Forming Layer

In this step, the relief forming layer is preferably cross-linked before the relief forming layer of the printing plate precursor obtained as described above is subjected to laser engraving.

When the relief forming layer contained the (C) cross-linking agent, it is preferred that the relief forming layer be subjected to irradiation of an active light and/or heating so as to be cross-linked.

As used herein, “cross-linking” refers to a concept including a cross-linking reaction by which molecules of binder polymers are bound each other, and also including a polymerization reaction between polymerizable compounds and a curing reaction of a relief forming layer due to the reaction between the binder polymer and the polymerizable compound.

The active light used for cross-linking of the relief forming layer is generally irradiated on the whole surface of the relief forming layer. Examples of the active light include a visible light, an ultraviolet light, and an electron beam. Among these, an ultraviolet light is the most commonly used active light. If a support side of the relief forming layer is a back side, the active light may be irradiated only on the front side of the relief forming layer. When the support is a film which is transparent to the active light, it is preferable that the active light be irradiated also from the back side of the relief forming layer. The irradiation of the active light from the front side of the relief forming layer may be performed either with a protective film thereon when it exists, or after the protective film is peeled off. Since polymerization inhibition may occur in the presence of oxygen, the active light may be irradiated on the relief forming layer after the relief forming layer is covered with a vinyl chloride sheet, and the system is evacuated.

When the relief forming layer contains a thermal polymerization initiator (the photopolymerization initiator mentioned above can be the thermal polymerization initiator), the relief forming layer may be cross-linked by heating a printing plate precursor (a step of cross-linking by heating). Examples of the heating method include a method of heating the printing plate precursor in a hot air oven or in a far-infrared oven for a predetermined time and a method of allowing the printing plate precursor in contact with a heated roll for a predetermined time.

As a cross-linking method of the relief forming layer, thermal cross-linking is preferred from the viewpoint that the relief forming layer can be cured (cross-linked) from the surface to the inside of the relief forming layer.

By cross-linking the relief forming layer, a relief formed after laser engraving becomes sharp and advantages are provided that adhesiveness of engraving residue generated during laser engraving is restricted.

Engraving by Laser Irradiation

In this step, a relief layer of the printing plate precursor obtained as mentioned above is engraved by laser irradiation.

By this step, a printing plate having a desired relief layer may be produced.

Specifically, a relief layer is formed by engraving a relief forming layer by irradiating a laser corresponding to an image to be formed. Preferably, the relief forming layer is subjected to scanning laser irradiation with a laser head controlled by a computer in accordance with the digital data of the image to be formed.

In the engraving step, infrared laser is preferably employed. When infrared laser is irradiated to a relief forming layer, molecules in the relief forming layer vibrate to generate heat. When a high power laser such as a carbon dioxide laser or a YAG laser is used as the infrared laser, the portion of the relief forming layer, which is irradiated with the laser light, generates a large amount of heat, and molecules in the relief forming layer are cleaved or ionized to be selectively removed; thus, the relief forming layer is engraved. The advantage of laser engraving is that structures may be controlled 3-dimensionally because the engraving depth may be arbitrarily set. For example, by shallowly engraving a portion by which fine dots are printed, or by engraving the portion such that the portion has a shoulder, the relief which will not be tumbled by printing pressure may be formed. By deeply engraving groove portions by which small outline characters are printed, the grooves are hardly filled with ink to inhibit damages of the outline characters.

In particular, when the relief forming layer is engraved by infrared laser corresponding to the absorption wavelength of the (E) photothermal converting agent, selective removal of the relief forming layer with higher sensitivity is possible, and a relief layer having a sharp image is obtained. Preferable examples of the infrared lasers employed in these steps include a carbon dioxide laser or a semiconductor laser. Since the light source may be placed close to the relief forming layer, and minute and high-intensity parallel lights may be irradiated, the variation of engraving width along the depth direction of the relief forming layer is small, and the relief forming layer may be removed in a uniform width at the engraving depth of 5 μm to 600 μm. In view of this, a fiber-coupled infrared semiconductor laser is particularly preferably employed.

In general, semiconductor lasers are more effective in laser oscillation and more cost-effective compared with CO₂ laser, and it is possible to make them smaller in size. Arraying them is easy because of their small size. Further, the shape of the beam may be controlled by treating the fibers. As a semiconductor laser, one having a wavelength of 700 nm to 1,300 nm may be employed. The semiconductor laser preferably has a wavelength of 800 nm to 1200 nm, more preferably 860 nm to 1200 nm, and particularly preferably 900 nm to 1100 nm.

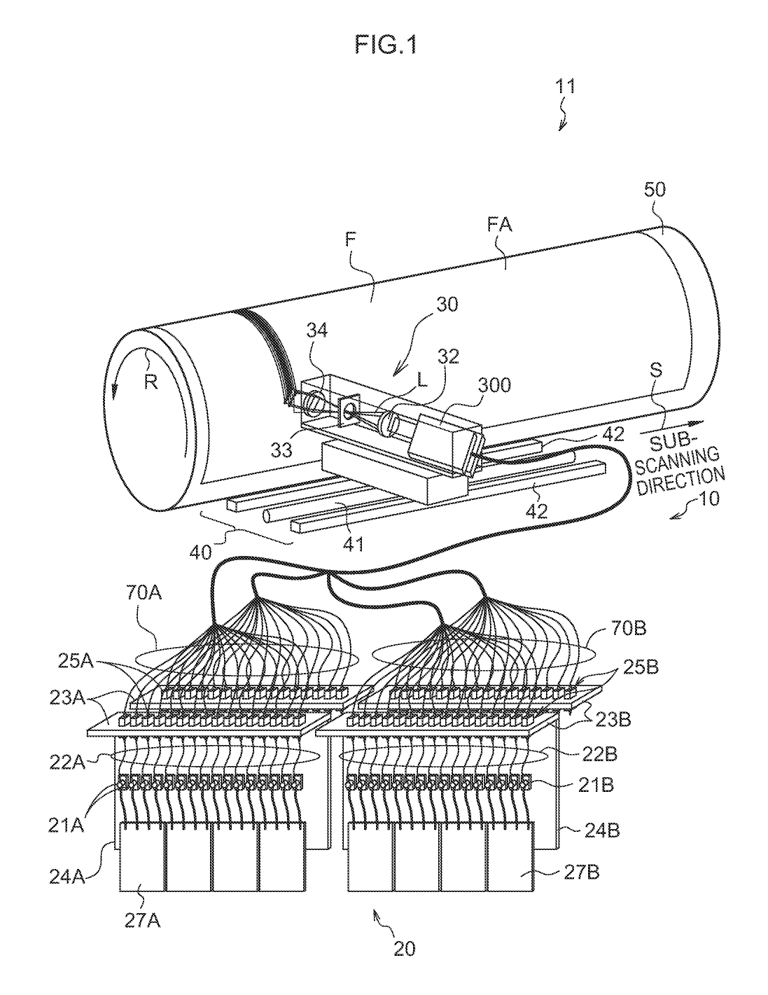

Hereinbelow, an embodiment of a plate-making apparatus 11, having a fiber-coupled semiconductor laser recorder 10, which can be used for the method of making a printing plate of the present invention, will be described with reference to FIG. 1.

In the plate-making apparatus 11, having the fiber-coupled semiconductor laser recorder 10, which can be used in the present invention, while a drum 50 on the circumference surface of which a printing plate precursor F (recording media) is mounted rotates in the main scanning direction R, scanning with an exposure head 30 is performed at a predetermined pitch in a sub-scanning direction (the direction of the arrow S shown in FIG. 1) orthogonal to the main scanning direction, at the same time as when plural laser beams corresponding to an image data of an image for engraving (an image to be recorded) are simultaneously emitted on the printing plate precursor F, whereby a two-dimensional image is recorded (by engraving) on the printing plate precursor F at a high speed. When a narrow region is engraved (minute engraving of fine lines, dots or the like), the printing plate precursor F is shallowly engraved. When a broad region is engraved, the printing plate precursor F is deeply engraved.

As shown in FIG. 1, the plate-making apparatus 11 has at least: a drum 50, on which a printing plate precursor F to be engraved by a laser beam to record an image is provided, and which rotates in the direction of the arrow R shown in FIG. 1 so that the printing plate precursor F moves in the main scanning direction; and a laser recorder 10. The laser recorder 10 has at least: a light source unit 20 which generates plural laser beams; an exposure head 30 by which the printing plate precursor F is exposed to plural laser beams generated by the light source unit 20; and an exposure head moving unit 40 which moves the exposure head 30 along the sub-scanning direction S.

The light source unit 20 has at least: semiconductor lasers 21A and 21B constituted by broad-area semiconductor lasers each of which is individually coupled to one end of each of optical fibers 22A and 22B; light source boards 24A and 24B, on the surface of which the semiconductors 21A and 21B are placed; adapter boards 23A and 23B, each of which is attached to one end of each of the light source boards 24A and 24B vertically, and on which plural (the same number as that of 21A and 21B) adapters to SC connectors 25A and 25B are provided; and LD driver boards 27A and 27B, each of which is attached to the other end of each of the light source boards 24A and 24B horizontally, and on which an LD driver circuit (not shown) that drives semiconductor lasers 21A and 21B in accordance with an image data of an image to be engraved (recorded) on a printing plate precursor F is provided.

The exposure head 30 includes a fiber array unit 300 that emits combined laser beams each of which is emitted from plural semiconductor lasers 21A and 21B. To the fiber array unit 300, laser beams are transmitted, the laser beams being emitted from each of the semiconductor laser 21A and 21B via plural optical fibers 70A and 70B each of which is connected to the SC connectors 25A and 25B each of which is connected to each of the adapter boards 23A and 23B.

As shown in FIG. 1, in the exposure head 30, a collimator lens 32, an aperture member 33 and an imaging lens 34 are placed sequentially in this order from the side of the fiber array unit 300. The aperture member 33 is placed such that the opening is at the far-field position when viewed from the side of the fiber array unit 300, whereby the amount of light may be equally restricted with respect to each of the laser beams emitted from the ends of the plural optical fibers 70A and 70B in the fiber array unit 300.

A laser beam forms an image near the exposure face (surface) FA of a printing plate precursor F through imaging devices including the collimator lens 32 and the imaging lens 34.

Since it is possible to change a beam shape of the fiber-coupled semiconductor laser, in the present invention, it is desired that the imaging position be within the range inside the exposure face FA (in the direction of the travel of a laser beam) to control the diameter of a beam on the exposure surface (the surface of a relief forming layer) within a range of 10 to 80 μm from the viewpoint of efficient engraving, good reproduction of thin lines and the like.

In the exposure head moving unit 40, a ball screw 41 and two rails 42 are provided in such a manner that the longitudinal directions of the ball screw and rails are along the sub-scanning direction. By actuating a sub-scanning motor (not shown) which rotates the ball screw 41, a mount unit on which the exposure head 30 is provided may be moved in the sub-scanning direction guided by the rails 42. The drum 50 can be rotated in the direction of the arrow R shown in FIG. 1 by actuating a main scanning motor (not shown), whereby main scanning is performed.

In order to control a desired shape of an engraved region, a shape of the engraved region can be changed by changing the amount of energy supplied to a laser without changing the beam shape of a fiber-coupled semiconductor laser.

Specifically, a method of controlling by changing the output of the semiconductor laser or a method of controlling by changing the time of laser irradiation is employed.

Step (2)

In the step (2), the surface of the relief forming layer engraved in the step (1) is treated with an emulsion cleaner.

First, the emulsion cleaner used in this step will be described.

Emulsion Cleaner

An emulsion cleaner used in this step is preferably an emulsion cleaner at least includes: an organic solvent which dissolves a thermal decomposition product of the (A) specific binder; at least one surfactant selected from the group consisting of anionic surfactants and nonionic surfactants; and water.

Examples of the emulsion cleaner include a water-in-oil emulsion disclosed in European Patent Application No. 463016 and a micro-emulsion cleaner disclosed in WO 99/627733. Other known examples of the emulsion cleaner include cleaners as those described in JP-A No. 53-2102, JP-A No. 6-32081, JP-A No. 9-249899, JP-A No. 2003-103956, JP-A No. 2007-199473, JP-A No. 2008-1059, JP-A No. 2008-80635, and JP-A No. 2008-188876.

A commercially-available MULTICLEANER (trade name, manufactured by Fujifilm Corporation) may also be preferably employed.

Composition of Emulsion Cleaner

The emulsion cleaner used in this step will be described in detail.

The composition of the emulsion cleaner in the present invention includes at least (1) an oil phase containing an organic solvent which dissolves a thermal decomposition product of the (A) specific binder, (2) at least one surfactant selected from the group consisting of anionic surfactants and nonionic surfactants, and (3) water, and may further include an aqueous phase containing (4) a polysaccharide extracted from soybean, (5) at least one compound selected from the group consisting of phosphoric acid, polymer phosphoric acid, alkali metal salts thereof, and organic phosphonic acid, (6) at least one compound selected from organic carboxylic acids, (7) a nitrate, a sulfate, a disulfate, or the like, and may further include, as required, (8) a water-soluble colloidal substance, (9) a wetting agent, (10) a thixotropic agent, (11) a pH adjuster.

Other than the components mentioned above, any of preservatives, antimicrobials and/or dyes may be added to the emulsion cleaner used in the present invention.

Examples of the organic solvent which dissolves a thermal decomposition product of the (A) specific binder include petroleum hydrocarbons (aliphatic hydrocarbons), aromatic hydrocarbons, monoterpene hydrocarbons, fatty acid triglycerides, and mixtures thereof. Among these, from the viewpoint of protecting a relief forming layer (relief layer), aliphatic hydrocarbon solvents are preferably used.

The solvent has a SP value of preferably from 6.6 to 12.7, more preferably from 7 to 11.4, and most preferably from 7.5 to 10.1.

The SP value of the present invention is calculated by Fedors equation when the chemical structure is obvious; that is, for example, in the case of a solvent consist of a single material. In the case of commercially-available products whose chemical structures are not disclosed, the SP value is, for example, calculated by Hildebrand's equation (the equation below) in which the SP value is calculated from the measured surface tension.

SP≈K(γ/V^{1/3})^{0.43}

In the equation, K is a constant, and V represents a molecular volume or a molar volume.

Petroleum Hydrocarbons (Aliphatic Hydrocarbons)

Examples of petroleum hydrocarbons mainly include aliphatic hydrocarbons (such as n-hexane or n-heptane), and also include mineral spirit and high-boiling point petroleum solvents (such as ink oil). Aliphatic hydrocarbons may dissolve many types of resins such as rhodine, rhodine esters and maleic acid resins, and therefore, are preferably employed as an emulsion cleaner used in the present invention.

The aliphatic hydrocarbon solvents do not have a ring structure in the molecules thereof, and include hydrocarbons containing a linearly or branched carbon atom chain. Among these, solvents having a boiling point of from 120° C. to 320° C. in the petroleum fraction are particularly preferred.

Examples of commercially-available products of the solvents include EXXSOL D-80 (trade name; SP value: 7.3) manufactured by Exxon Chemicals.

Preferable examples of petroleum hydrocarbons include benzine, rubber volatile oil, volatile soybean oil, mineral spirit, and cleaning solvents. Mineral spirit (boiling point: 140° C. to 205° C.) and cleaning solvent (boiling point: 150° C. to 210° C.) are preferred. These petroleum hydrocarbons are stipulated by JIS standard of industrial gasoline (JIS K2201 (1991)). Petroleum hydrocarbons having a large amount of aromatic compounds and petroleum hydrocarbons having a small amount of aromatic compounds are commercially available.

Examples of the commercially-available products include CLEANSOL (trade name; SP value: 7.3) manufactured by Nippon Oil Corporation, A SOLVENT (trade name; SP value: 7.3) manufactured by Nippon Oil Corporation, and MINERAL SPIRIT A (trade name; SP value: 7.3) manufactured by Nippon Oil Corporation.

Other examples of the petroleum hydrocarbons include hexane, heptane, octane, nonane, decane, dodecane, cyclohexane, toluene, and xylene; ISOPAR C, ISOPAR E, ISOPAR G, ISOPAR H, ISOPAR L, ISOPAR M, NAPHTHA No. 3, NAPHTHA No. 5, NAPHTHA No. 6, NAPHTHA No. 7, SOLVESSO 100, SOLVESSO 150, SOLVESSO 200, EXXSOL D30, EXXSOL D40, EXXSOL D80, and EXXSOL D100 (all trade names; manufactured by Exxon Chemicals); and IP SOLVENT 1016, IP SOLVENT 1620, IP SOLVENT 2028, and IP SOLVENT 2835 (all trade names; manufactured by Idemitsu Petroleum Co., Ltd.). The SP values of these commercially-available products are similar to that of n-hexane (i.e., 7.3).

Aromatic Hydrocarbons

Aromatic hydrocarbons have higher dissolving capacity than those of the aliphatic hydrocarbons. Examples of the aromatic hydrocarbons mainly include toluene and xylene, and toluene is preferably employed.

Examples of the aromatic hydrocarbon solvents roughly include two types of solvents; one of which includes, as a main component, aromatic compounds having 9 carbon atoms and having a boiling point of from 155 to 175° C.; and another of which includes, as a main component, aromatic compounds having 10 carbon atoms and having a boiling point of from 180 to 210° C. Examples of the aromatic hydrocarbon solvents include SOLVENT series (trade name, manufactured by Nippon Petrochemicals Co., Ltd.), SWASOL series (trade name, manufactured by Maruzen Petrochemical Co., Ltd.), and EXXSOL (trade name, manufactured by Exxon Chemicals).

Specific examples of the aromatic hydrocarbon solvents include SOLVESSO 100 (trade name; SP value: 8.8) manufactured by Ogura Kosan Kabushiki Kaisha, SWASOL 310 (trade name; SP value: 8.26) manufactured by Exxon, SWASOL 1000 (trade name; SP value: 8.43) manufactured by Exxon, SWASOL 1500 (trade name; SP value: 8.37) manufactured by Exxon, S-100 (trade name; SP value: 8.36) manufactured by Esso, and S-150 (trade name; SP value: 8.44) manufactured by Esso.

Monoterpene Hydrocarbons

As monoterpene hydrocarbons, a variety of known compounds may be employed, and examples of the monoterpene hydrocarbons include α-pinene, β-pinene, 3-carene, camphene, D-limonene, L-limonene, dipentene, terpinolene, α-terpinene, α-terpineol, myrcene, ocimene, and p-cymene. Among these monoterpene hydrocarbons, D-limonene, dipentene, or the like is preferred. These monoterpene hydrocarbons are used individually, or two or more monoterpene hydrocarbons are used in combination.

Fatty Acid Triglycerides

As fatty acid triglycerides, a variety of know compounds may be employed, and examples of the fatty acid triglycerides include a compound represented by the following formula (1):

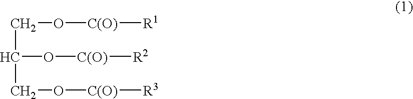

In the formula (1), R¹, R², and R³ may be the same as or different from each other, and each represent a saturated or unsaturated aliphatic hydrocarbon group having 5 to 23 carbon atoms.

In the formula (1), each of R¹, R², and R³ represents a saturated or unsaturated aliphatic hydrocarbon group having 5 to 23, and preferably 7 to 17 carbon atoms and may have a hydroxyl group. Specific examples of R¹, R², and R³ include a n-hexyl group, a n-heptyl group, a n-octyl group, a n-nonyl group, a n-decyl group, a n-undecyl group, a n-dodecyl group, a n-tridecyl group, a n-tetradecyl group, a n-pentadecyl group, a n-hexadecyl group, a n-heptadecyl group, a n-octadecyl group, a n-nonadecyl group, a 2-hexenyl group, a 2-heptenyl group, a 2-octenyl group, a pentadecenyl group, a heptadecenyl group and a 9-octadecenyl group.

As fatty acid triglycerides of the present invention, vegetable oils may also be used.

Therefore, a part of or entire group represented by R¹—C(O)—, R²—C(O)—, or R³—C(O)—in the formula (1) may be a fatty acid residue of a vegetable oil, such as a residues of caproic acid, caprylic acid, capric acid, lauric acid, myristic acid, palmitic acid, palmitoleic acid, stearic acid, oleic acid, linolic acid, linolenic acid, arachidic acid, eicosenic acid, behenic acid, erucic acid, lignoceric acid, dihydroxystearic acid, ricinoleynoic acid or the like.

Specific examples of the vegetable oils which may be used as the fatty acid triglycerides of the present invention include avocado oil, olive oil, camellia oil, apricot kernel oil, kukui nuts oil, grape seed oil, sesame oil, safflower oil, sweet almond oil, soybean oil, corn oil, pistachio nut oil, castor oil, sunflower seed oil, hazel nuts oil, jojoba oil, macadamia nuts oil, meadow form oil, peanut oil, canola oil, rose hips oil, and coconut oil. Among these fatty acid triglycerides, safflower oil, soybean oil, canola oil, and corn oil are preferably employed. Such vegetable oils may be used individually, or two or more vegetable oils may be used in combination.

In the emulsion cleaner employed in this step, the content of the (1) organic solvent which dissolves a thermal decomposition product of the (A) specific binder is suitably from 3 to 50% by mass, and more preferably from 10 to 40% by mass, with respect to the total mass of the emulsion cleaner.

Since the (1) organic solvent which dissolves a thermal decomposition product of the (A) specific binder do not mix with water, it is used in a well-mixed state when in use. Here, a (2) surfactant is used in order to improve the dispersion stability. Examples of the surfactant which may be employed include anionic surfactants and nonionic surfactants.

Preferable range of the HLB of surfactants to be used is from 3 to 16, and more preferably from 5 to 10. By using surfactants having a HLB within the ranges, an emulsified emulsion may be formed.

Examples of anionic surfactants include fatty acid salts, abietates, hydroxyalkane sulfonates, alkanesulfonates, dialkylsulfosuccinates, linear alkylbenzene sulfonates, branched alkylbenzene sulfonates, alkylnaphthalene sulfonates, alkylphenoxypolyoxyethylenepropyl sulfonates, polyoxyethylene alkylsulfophenyl ether salts, sodium N-methyl-N-oleyltaurates, disodium N-alkylsulfosuccinic acid monoamides, petroleum sulfonates, sulfonated castor oil, sulfonated beef tallow oil, sulfates of fatty acid alkyl esters, alkyl sulfates, polyoxyethylene alkylethersulfates, fatty acid monoglyceride sulfates, polyoxyethylene alkylphenylethersulfates, polyoxyethylene styrylphenylether sulfates, alkyl phosphates, polyoxyethylene alkylether phosphates, polyoxyethylene alkylphenylether phosphates, partially-saponified styrene-maleic anhydride copolymers, partially-saponified olefine-maleic anhydride copolymers, and naphthalene sulfonate formalin condensates. Among these, dialkylsulfosuccinates, alkylsulfates and alkylbenzenesulfonates are particularly preferably employed.

Examples of nonionic surfactants include polyoxyethylene alkyl ethers, polyoxyethylene alkyl phenyl ethers, polyoxyethylene polystyryl phenyl ethers, polyoxyethylene polyoxypropylene alkyl ethers, glycerine fatty acid partial esters, sorbitan fatty acid partial esters, pentaerythritol fatty acid partial esters, propyleneglycol monofatty acid esters, sucrose fatty acid partial esters, polyoxyethylene sorbitan fatty acid partial esters, polyoxyethylene sorbitol fatty acid partial esters, polyethyleneglycol fatty acid esters, polyglycerin fatty acid partial esters, polyoxyethylated castor oil, polyoxyethylene glycerin fatty acid partial esters, fatty acid diethanolamides, N,N-bis-2-hydroxyalkylamines, polyoxyethylenealkylamines, triethanolamine fatty acid esters, and trialkylamineoxides. Among these, polyoxyethylated castor oil and sorbitan fatty acid partial esters are preferably employed.

Two or more types of these surfactants may be used in combination.

The amount of the (2) surfactant used in the emulsion cleaner is not particularly restricted, and preferably from 0.5 to 10% by mass with respect to the total mass of the emulsion cleaner.

In the emulsion cleaner used in this step, the aqueous phase may contain (4) polysaccharides extracted from soybeans, that is, water-soluble soybean polysaccharides. As the water-soluble soybean polysaccharides, those having a film formability are preferred. Examples of the water-soluble soybean polysaccharides include those having rhamnose, fucose, arabinose, xylose, galactose, glucose and/or uronic acid as constituent sugar(s) and having an average molecular weight of from 50,000 to 100,000.

The content of the water-soluble soybean polysaccharides in the emulsion cleaner is from 5 to 20% by mass with respect to the total mass of the emulsion cleaner.

The soybean polysaccharide is used in the form of a uniform aqueous solution obtained by dissolving the polysaccharide in water or hot water at a temperature of 50° C. or less. A method of producing such water-soluble soybean polysaccharides is described in JP-A No. 5-32701, for example.

Examples of commercially-available product of the soybean polysaccharides include SOYAFIVE-S-LN (trade name, manufactured by Fuji Oil Co., Ltd.).

In the present invention, soybean polysaccharides whose 10% by mass aqueous solution has a viscosity (25° C.) of from 5 to 10 cp are preferably used.

In the emulsion cleaner used in this step, the aqueous phase may contain (5) at least one compound selected from the group consisting of phosphoric acid, polymer phosphoric acid, an alkali metal salt thereof, and organic phosphonic acid. Specific examples of these compounds include phosphoric acid, sodium phosphate, potassium phosphate, lithium phosphate, pyrophosphoric acid, sodium pyrophosphate, potassium pyrophosphate, lithium pyrophosphate, tripolyphosphoric acid, sodium tripolyphosphate, potassium tripolyphosphate, lithium tripolyphosphate, tetraphosphoric acid, sodium tetraphosphate, potassium tetraphosphate, lithium tetraphosphate, hexametaphosphoric acid, sodium hexametaphosphate, potassium hexametaphosphate, lithium hexametaphosphate, inositol hexaphosphoric acid (another name: phytic acid), methylene diphosphonic acid, 1-hydroxyethane-1,1-disulfonic acid, nitrilotrisphosphonic acid, N-carboxymethyl N,N-di(methylenephosphonic acid), hexamethylenediamine-tetra(methylenephosphonic acid), ethylenediamine-tetra(methylenephosphonic acid), diethylenetriamine-penta(methylenephosphonic acid), N,N-di(carboxymethyl)-N-methylenephosphonic acid, N-(2-hydroxyethyl)-N,N-di(methylenephosphonic acid), N-hydroxymethyl-N,N′,N′-ethylenediaminetris(methylenephosphonic acid), N-hydroxyethyl-N′,N′-diethylethylenediamine-N,N,N′,N′-tatra(methylenephosphonic acid), di(2-hydroxypropylene)triaminepenta(methylenephosphonic acid), and tri(2-hydroxypropylene)tetraaminehexa(methylenephosphonic acid).

These compounds are commercially available and sold as, for example, “DEQUEST” series (trade name) manufactured by Monsanto Chemical Company and “WAYPLEX” series (trade name) manufactured by Wayland Chemical Division of Philip A Hant Chemical Corp.

These compounds may be used individually, or two or more of these compounds may be used in combination.

Among these, phosphoric acid, hexametaphosphoric acid, pyrophosphoric acid, alkali metal salts thereof, and phytic acid are preferably used.

The content of the (5) compound in the emulsion cleaner is appropriately from 0.1 to 15% by mass, and more preferably from 0.5 to 10% by mass.

In the emulsion cleaner used in this step, the aqueous phase may contain (6) an organic carboxylic acid. Examples of the organic carboxylic acid include citric acid, acetic acid, malonic acid, tartaric acid, malic acid, lactic acid, levulinic acid, butyric acid, maleic acid and picolinic acid. As the component (6), one or more types of organic carboxylic acids may be employed. Among these, citric acid, malic acid, maleic acid or the like is preferably employed.

The amount of the organic carboxylic acids used is generally 0.5 to 10% by mass, and more preferably 1 to 5% by mass based on the total mass of the emulsion cleaner.

In the emulsion cleaner used in this step, the aqueous phase may contain (7) a nitrate, a sulfate, or a bisulfate.

As the nitrate, a water-soluble nitrate is employed, and examples of the water-soluble nitrate include metal nitrates such as zinc nitrate, cobalt nitrate, magnesium nitrate, sodium nitrate, potassium nitrate, nickel nitrate, bismuth nitrate, tin nitrate, strontium nitrate, cesium nitrate or cerium nitrate; and ammonium nitrate. These nitrates may be used individually, or two or more of these nitrates may be used in combination.

The amount of the water-soluble metal nitrate used in the emulsion cleaner is generally from 0.5 to 10% by mass, and more preferably from 1 to 5% by mass, with respect to the total mass of the emulsion cleaner.

Examples of the sulfate include sodium sulfate, potassium sulfate, and aluminum sulfate.

The bisulfate is represented by the following formula M(HSO₄)ₙ, in which M represents a metal atom, and n represents the valence of the M atom. Examples of the bisulfate include strontium hydrogen sulfate, potassium hydrogen sulfate, calcium hydrogen sulfate, thallium hydrogen sulfate, sodium hydrogen sulfate, lead hydrogen sulfate, bismuth hydrogen sulfate, magnesium hydrogen sulfate, rhodium hydrogen sulfate.

These sulfates and bisulfates may be used individually, or one or more of these may be used in combination.

In the emulsion cleaner used in the present invention, the amount of the sulfate and/or bisulfate to be used is generally from 0.01 to 5% by mass, and more preferably from 0.1 to 3% by mass, with respect to the total mass of the emulsion cleaner.

The emulsion cleaner may contain (7) at least one selected from a nitrate, a sulfate and a bisulfate. The total amount of the components is appropriately from 0.5 to 10% by mass, and more preferably from 1 to 8% by mass.

The emulsion cleaner used in this step may contain a (8) water-soluble colloidal substance. The water-soluble colloidal substance is used as a viscosity modifier, and is appropriately used such that the viscosity of the whole emulsion cleaner at 25° C. is from 10 cps to 1000 cps.

Preferable specific examples of the water-soluble colloidal substance include natural products such as dextrin, cyclodextrin, alginic acid salts or cellulose derivatives (e.g., carboxymethyl cellulose, carboxyethyl cellulose, hydroxyethyl cellulose, or methyl cellulose) and denatured products thereof; and synthetic products such as polyvinyl alcohol and derivatives thereof, polyvinylpyrrolidone, polyacrylamide and copolymers thereof, acrylate copolymer, vinyl methyl ether/maleic anhydride copolymers, vinyl acetate/maleic anhydride copolymers or styrene/maleic anhydride copolymers. These substances may be used individually, or one or more of these substances may be used as a mixture. In order to make the viscosity range within the above-mentioned range, the amount of the water-soluble colloidal substance to be used may be from 1 to 24% by mass, and more preferably from 3 to 20% by mass, with respect to the total mass of the emulsion cleaner.

The emulsion cleaner employed in this step may contain a (9) wetting agent.

When the wetting agent is used, the emulsion cleaner is provided with good spread characteristics, and drying of the emulsion cleaner is reduced, which improves the usability of the emulsion cleaner.

Examples of suitable wetting agents include compounds represented by the following formula HO—(R-0)ₙ—H, in which R represents —CₘH₂ₘ— where m is an integer of from 2 to 6; and n is from 1 to 500. Examples of the compounds represented by the formula include ethylene glycol, propylene glycol, butylene glycol, pentanediol, hexylene glycol, diethylene glycol, triethylene glycol, tetraethylene glycol, polyethylene glycol, dipropylene glycol and tripropylene glycol. Other useful examples of wetting agent include glycerin, sorbitol and pentaerythritol.

When the amount of wetting agent to be used is from 1 to 30% by mass with respect to the total mass of the emulsion cleaner, an advantageous effect is observed. The amount is more preferably from 2 to 20% by mass.

The emulsion cleaner used in this step may contain a (10) thixotropy agent.

Thixotropy agents provide good operating characteristics when a printing surface is treated with a sponge or the like, because, when a thixotropy agent is included in a liquid, the viscosity of the liquid decreases under a dynamic pressure and increases when the liquid is left to stand. Examples of suitable thixotropy agents include fine powder of silicic acid, pumice, calcium carbonate and zeolite.

The amount of the thixotropy agent to be used is appropriately from 1 to 10% by mass, and preferably from 2 to 7% by mass, with respect to the total mass of the emulsion cleaner.

The emulsion cleaner used in this step is usually used under an acidic condition adjusted generally to a pH of from 1 to 4. In order to adjust the pH within this range, a (11) pH adjuster is preferably used. Examples of the pH adjuster include acids such as sulfuric acid, phosphorous acid, citric acid, acetic acid, oxalic acid, malonic acid, tartaric acid, malic acid, lactic acid, levulinic acid, butyric acid, maleic acid, and picolinic acid. An alkali such as sodium hydroxide, potassium hydroxide or lithium hydroxide may be used in combination with the acids.

In the emulsion cleaner used in this step, the remaining component of the aqueous phase is (3) water. The amount of the water is suitably from 45 to 85% by mass, and more preferably from 50 to 80% by mass, with respect to the total mass of the emulsion cleaner.

One example of the methods of producing an emulsion cleaner used in the present invention is a method in which an aqueous phase and an oil phase are prepared respectively; the oil phase is added by dropping into the aqueous phase to produce a dispersion; and the dispersion is further emulsified by a homogenizer.

As the method of cleaning an engraved relief forming layer using an emulsion cleaner, for example, a method is used, in which the printing surface of a printing plate is wiped with a waste cloth or the like soaked with the emulsion cleaner; the printing plate is left to stand for an appropriate time; and then the printing plate is washed with water to wipe out the emulsion cleaner.

A brush may be used in combination for the washing. Specifically, a method may be used, in which an engraved surface is scrubbed with a brush in the presence of the emulsion cleaner using a brush washing machine.

Other Steps

The method of making a printing plate of the present invention preferably includes the following step(s) (3) and/or (4), after the step (2).

Step (3): Step of drying the engraved relief layer (Drying Step)

Step (4): Step of applying energy to the relief layer after engraving to further cross-link the relief layer (Post-Crosslinking Step)

After the step (2) in which the engraved surface is cleaned, it is preferred to additionally perform the step (3) in which the engraved relief layer is dried, in order to volatilize the emulsion cleaner.

The step (4) may further be added as required, in order to further cross-link the relief forming layer.

The additional cross-linking step (4) makes a relief formed by engraving more rigid.

As described above, a printing plate having a relief layer on which a desired image is formed is obtained.

The thickness of the relief layer in the printing plate is, from the viewpoint of satisfying a variety of flexography properties such as abrasion resistance or ink transfer properties, preferably from 0.05 to 10 mm, more preferably from 0.05 to 7 mm, and particularly preferably from 0.05 to 0.3 mm.

In addition, it is preferable that the Shore A hardness of the relief layer in the relief printing plate be from 50° to 90°.

When the Shore A hardness of the relief layer is 50° or more, even when a fine dot formed by engraving undergoes a strong printing pressure of a letterpress printing machine, the dot does not fall down and is not crushed, and normal printing may be performed. On the other hand, when the Shore A hardness of the relief layer is 90° or less, even in the case of flexography in which a printing pressure is kiss touch, printing shortage in a solid area may be prevented.

The Shore A hardness in the present specification is a value obtained by using a durometer (spring-type rubber hardness scale) for indentation-deforming the surface of an object to be measured with an indenter (also called a press needle), and measuring the value of the deformation amount (indentation depth).

The printing plate produced according to the production method of the invention allows printing with an oil-based ink or a UV ink using a letterpress printing machine, and also allows printing with a UV ink using a flexographic printing machine.

Embodiments of the present invention are described below.

<1> A method of making a printing plate, comprising in the following order:

engraving by laser irradiation a relief forming layer of a printing plate precursor, the relief forming layer comprising a binder polymer having a glass transition temperature (Tg) of 20° C. or higher; and

treating a surface of the engraved relief forming layer with an emulsion cleaner.

<2> The method of making a printing plate according to <1>, wherein the glass transition temperature of the binder polymer is 25° C. or higher.
<3> The method of making a printing plate according to <1>, wherein the binder polymer comprises at least one selected from the group consisting of polystyrenes, polyesters, polyamides, polyureas, polyamide-imides, polyurethanes, polysulfones, polyether sulfones, polyimides, polycarbonates, hydrophilic polymers comprising a hydroxyethylene unit, (meth)acrylic resins, acetal resins, epoxy resins, rubbers, and thermoplastic elastomers.
<4> The method of making a printing plate according to <1>, wherein the binder polymer comprises a polymer which has a carbon-carbon unsaturated bond in a molecule thereof.
<5> The method of making a printing plate according to <1>, wherein the binder polymer comprises at least one of a polyvinyl alcohol or a derivative thereof.
<6> The method of making a printing plate according to <1>, wherein the total content of the binder polymer in the relief forming layer is from 15% by mass to 75% by mass with respect to the total solid content of the relief forming layer.
<7> The method of making a printing plate according to <1>, wherein the relief forming layer further comprises a photothermal converting agent.
<8> The method of making a printing plate according to <7>, wherein the photothermal converting agent comprises carbon black.
<9> The method of making a printing plate according to <7>, wherein the content of the photothermal converting agent is from 0.01% by mass to 20% by mass with respect to the total solid content of the relief forming layer.
<10> The method of making a printing plate according to <1>, wherein the relief forming layer further comprises a cross-linking agent.
<11> The method of making a printing plate according to <1>, wherein the laser irradiation is performed using a fiber-coupled semiconductor laser.
<12> The method of making a printing plate according to <1>, wherein the emulsion cleaner comprises an organic solvent which dissolves a thermal decomposition product of the binder polymer; at least one surfactant selected from the group consisting of anionic surfactants and nonionic surfactants; and water.
<13> The method of making a printing plate according to <12>, wherein the organic solvent comprises:

a petroleum hydrocarbon, an aromatic hydrocarbon, a monoterpene hydrocarbon, or a fatty acid triglyceride; or

a mixture comprising at least two selected from the group consisting of a petroleum hydrocarbon, an aromatic hydrocarbon, a monoterpene hydrocarbon, and a fatty acid triglyceride.

<14> The method of making a printing plate according to <12>, wherein the content of the organic solvent is from 3% by mass to 50% by mass with respect to the total mass of the emulsion cleaner.
<15> The method of making a printing plate according to <1>, which is a method of making a flexographic printing plate.

### EXAMPLES

Hereinbelow, the present invention will be described in more detail by way of Examples; however, the present invention is not restricted to these Examples.

In the following Examples, the weight-average molecular weight (Mw) of a polymer indicates the value measured by the GPC method unless otherwise specified.

### Example 1

### Production of Support Coated with Adhesive Layer

### Preparation of First Coating Liquid for Adhesive Layer

A mixture of 260 parts by mass “VYLON” 31SS (trade name; toluene solution of unsaturated polyester resin, manufactured by Toyobo Co., Ltd.) and 2 parts by mass of “PS-8A” (trade name; benzoin ethyl ether, manufactured by Wako Pure Chemical Industries, Ltd.) was heated at 70° C. for 2 hours, and then cooled to 30° C. After 7 parts by mass of ethylene glycol diglycidyl ether dimethacrylate was added thereto, the resultant was mixed for 2 hours.

Further, 25 parts by mass of “CORONATE” 3015E (registered trademark; ethyl acetate solution of polyisocyanate resin, manufactured by Nippon Polyurethane Industry Co., Ltd.) and 14 parts by mass of “EC-1368” (trade name; industrial adhesive, manufactured by Sumitomo 3M Limited) were added to the thus-obtained mixture, thereby obtaining a first coating liquid for an adhesive layer.

Preparation of Second Coating Liquid for Adhesive Layer

First, 50 parts by mass of “GOHSENOL” KH-17 (trade name; polyvinyl alcohol having a saponification degree of 78.5% to 81.5%; manufactured by The Nippon Synthetic Chemical Industry Co., Ltd.) was dissolved into a mixed solvent of 200 parts by mass of “SOLMIX” H-11 (trade name; alcohol mixture, manufactured by Japan Alcohol Trading Co., Ltd.) and 200 parts by mass of water at 70° C. for 2 hours. Then, 1.5 parts by mass of “BLEMMER” G (trade name; glycidylmethacrylate, manufactured by NOF Corporation) were added thereto, and the resultant was mixed for 1 hour. The thus-obtained mixture was further added with 3 parts by mass of a (dimethylaminoethyl methacrylate)/(2-hydroxyethyl methacrylate)/(methacrylic acid) copolymer (copolymerization ratio: 67/32/1), 5 parts by mass of “IRGACURE” 651 (registered trademark; benzyldimethylketal, manufactured by Ciba-Geigy Corporation), 21 parts by mass of “epoxy ester” 70PA (acrylic acid adduct of propylene glycol diglycidyl ether manufactured by Kyoeisha Chemical Co., Ltd.) and 20 parts by mass of ethylene glycol diglycidyl ether dimethacrylate, and mixed for 90 minutes. After being cooled to 50° C., the thus-obtained mixture was added with 0.1 parts by mass of “FLUORAD” TM FC-430 (registered trademark; manufactured by Sumitomo 3M Limited) and mixed for 30 minutes, thereby obtaining a second coating liquid for an adhesive layer.

Formation of Adhesive Layers

The first coating liquid for an adhesive layer was applied using a bar coater onto “LUMIRROR” T60 (registered trademark; polyester film manufactured by Toray Industries, Inc.), which had a thickness of 250 μm and was used as a support, to a thickness after drying of 40 μm. The resultant product was placed in an oven at 180° C. for 3 minutes to remove the solvent, thereby forming a first adhesive layer. Thereafter, the second coating liquid for an adhesive layer was applied onto the surface thereof using a bar coater to obtain a thickness after drying of 30 μm. The resultant product was dried in an oven at 160° C. for 3 minutes, thereby obtaining a laminate in which the first and second adhesive layers were successively formed on the support surface.

Production of Protective Film Having Slip Coat Layer

A coating liquid for a slip coat layer was obtained by dissolving 4 parts by mass of “GOHSENOL” AL-06 (trade name; polyvinyl alcohol having a saponification degree of 91% to 94%, manufactured by The Nippon Synthetic Chemical Industry Co., Ltd.) into a mixed solvent of 55 parts by mass of water, 14 parts by mass of methanol, 10 parts by mass of n-propanol and 10 parts by mass of n-butanol.

The coating liquid for a slip coat layer was applied onto a polyester film “LUMIRROR” S10 (registered trademark; manufactured by Toray Industries, Inc.) having a thickness of 100 μm using a bar coater to obtain a thickness after drying of 1.0 μm. The resultant was dried at 100° C. for 25 seconds, thereby obtaining a protective film having a slip coat layer on one side.

Preparation of Printing Plate Precursor

In a three-necked flask equipped with a stirring blade and a condenser tube, 50 parts by mass of polyvinyl butyral (#3000-1, trade name, manufactured by Denki Kagaku Kogyo Kabushiki Kaisya) as the binder polymer, 20 parts by mass of diethylene glycol as the plasticizer, and 30 parts by mass of ethanol as the solvent were placed, and heated at 70° C. for 120 minutes with stirring to dissolve the binder polymer.

To this polymer solution, 15 parts by mass of ethylenically-unsaturated monomer “LIGHT ACRYLATE” 14EG-A (trade name; diacrylate of polyethylene glycol 600, manufactured by Kyoeisha Chemical Co., Ltd.), 15 parts by mass of polyalkylene glycol (meth)acrylate monomer “BLEMMER PE-200” (trade name; manufactured by NOF Corporation), 1.5 parts by mass of PERBUTYL Z (registered trademark; t-butylperoxyoxide manufactured by NOF Corporation) as the polymerization initiator, and as the polymerization inhibitors, 0.005 parts by mass of “Q-1300” (trade name; N-nitrosophenylhydroxylamine ammonium manufactured by Wako Pure Chemical Industries, Ltd.), 3 parts by mass of ZnCl₂ (manufactured by Wako Pure Chemical) and 0.7 parts by mass of carbon black (trade name: SEAST 9H SAF-HS, manufactured by Tokai Carbon Co., Ltd.) were added. The resultant mixture was stirred for 30 minutes, thereby obtaining a fluid coating liquid 1 for a relief forming layer.

Here, the Tg of the polyvinyl butyral (#3000-1 manufactured by Denki Kagaku Kogyo Kabushiki Kaisya) was 68° C.

The carbon black was indicated as “CB” in Table 2.

The support having two adhesive layers obtained as described above was exposed to an ultra-high pressure mercury lamp at 1000 mJ/cm² from the second adhesive layer side of the support. The coating liquid 1 for a relief forming layer was then casted on the surface of the second adhesive layer side, and the resultant product was dried in an oven at 60° C. for 2 hours, thereby obtaining a laminate having a non-cross-linked relief forming layer, which laminate has a thickness of about 1,100 μm including the support.

The coating liquid 1 for a relief forming layer was further developed between the relief forming layer of the above-described laminate and the slip coat layer of the protective film having the slip coat layer, and lamination was carried out with a calendar roll heated to 85° C., thereby obtaining a laminate including a protective film, a slip coat layer, a non-cross-linked relief forming layer, a second adhesive layer, a first adhesive layer and the support in this order. The clearance of the calendar roll was adjusted in such a manner that the thickness of the laminate after the protected film was peeled off was 1,140 μm. The developed coating liquid 1 for a relief forming layer was left to stand for one day after the lamination, whereby the remaining solvent was diffused or air-dried and an additional non-cross-linked relief forming layer was formed.

The non-cross-linked relief forming layer was cross-linked by heating the thus-obtained laminate in an oven at 120° C. for 30 minutes, thereby obtaining a printing plate precursor provided on the protective film.

Preparation of Printing Plate

### 1. Engraving

As a semiconductor laser engraving apparatus, the laser recorder shown in FIG. 1 equipped with a fiber-coupled semiconductor laser (FC-LD) SDL-6390 (trade name, manufactured by JDS Uniphase Corporation; wavelength of 915 nm) having a maximum output of 8.0 W was used. After the protective film was peeled off, the printing plate precursor was subjected to raster engraving using the semiconductor laser engraving apparatus at a laser output of 6 W, a head speed of 100 mm/s, and a pitch setting of 2,400 DPI, thereby forming a solid area of 1 cm×1 cm.

Here, this semiconductor laser engraving apparatus was represented by “FC-LD” in the column of “Laser for Engraving” in Table 2.

### 2. Washing and Drying of Printing Surface

A laser-engraved, unwashed printing plate was washed for 5 minutes with an emulsion cleaner 1 described below in a brush washer (trade name: WASHERMAN; produced by Kamitani Co., Ltd.). Subsequently, after taken out of the brush washer, the printing plate was washed with tap water for 2 minutes and dried by spraying compressed air thereto.

Here, by washing with water, the emulsion cleaner was easily removed from the surface of the printing plate.

In this manner, the printing plate of Example 1 was obtained.

Emulsion Cleaner 1

| | |
|---|---|
| Surfactant: | |
| Dioctyl sulfosuccinate | 8 g |
| Polyglycol monoalkyl ether | 16 g |
| Oil phase: | |
| Canola oil fatty acid methyl ester | 15 g |
| Coconut oil fatty acid-2-ethyl-hexyl ester | 15 g |
| Aqueous phase: | |
| Water | 46 g |
| Calcium chloride | 0.07 g |

A mixture containing the above components was prepared and shaken at room temperature to obtain a clear emulsion.

Evaluation

### 1. Observation of Engraving Residue in Grooves Using Optical Microscope

After completion of the washing and drying of the printing surface as described above, the presence or absence of engraving residue in the grooves of the printing surface was observed using an optical microscope. Further, the same observation was made for the printing surface before the washing, and the state of engraving residue was compared between the printing surfaces before and after the washing. The results are shown in Table 2.

A: No residue was observed.

A⁻: Residue was observed at some parts.

B: Residue remained scattered on the printing surface compared to the printing surface before the washing.

B⁻: Residue was reduced compared to the printing surface before the washing, but not sufficiently.

C: Residue was not reduced compared to the printing surface before the washing.

### 2. Width of Engraved Thin Line

In the present evaluation, the minimum width of a thin line when the engraved depth (i.e., depth of an engraved portion) was 2 μm or more was measured. It was evaluated that, the smaller the width of the thin line, the more superior the engraving sensitivity and thin line-forming property, so that a highly-fine image can be obtained. The results are shown in Table 2. In Table 2, the width is indicated as “Minimum Width of Negative Thin Line”.

Here, the “engraved depth” refers to the difference of the positions (heights) of engraved and unengraved regions when the flexographic printing plate was viewed at a cross-section thereof, and the engraved depth was measured through observation using a SEM (transmission electron microscope).

### Example 2

The printing plate of Example 2 was obtained in the same manner as in Example 1 except that an emulsion cleaner 2 described below was used in place of the emulsion cleaner 1 used in “2. Washing and drying of printing surface” of Example 1.

Emulsion Cleaner 2

| | |
|---|---|
| Surfactant: | |
| Dioctyl sulfosuccinate | 14 g |
| Oil phase: | |
| Soybean oil | 34.5 g |
| Aqueous phase: | |
| Water | 51.5 g |

A mixture containing the above components was prepared and shaken at room temperature to obtain a clear emulsion (i.e., emulsion cleaner 2).

### Example 3

The printing plate of Example 3 was obtained in the same manner as in Example 1 except that an emulsion cleaner 3 described below was used in place of the emulsion cleaner 1 used in “2. Washing and drying of printing surface” of Example 1.

Emulsion Cleaner 3

| | |
|---|---|
| Surfactant: | |
| Dioctyl sulfosuccinate | 17.0 g |
| Oil phase: | |
| Decane | 415 g |
| Aqueous phase: | |
| Water | 41.5 g |

A mixture containing the above components was prepared and shaken at room temperature to obtain a clear emulsion (i.e., emulsion cleaner 3).

### Example 4

The printing plate of Example 4 was obtained in the same manner as in Example 1 except that an emulsion cleaner 4 described below was used in place of the emulsion cleaner 1 used in “2. Washing and drying of printing surface” of Example 1.

Emulsion Cleaner 4

First, an aqueous phase consisting of a mixture of 547 parts of purified water, 15 parts of metaphosphoric acid, 20 parts of magnesium nitrate, sodium hydroxide (pH regulator) in an amount to attain pH=2.0, 3 parts of tetrabutylphosphonium phosphoric acid salt, 150 parts of gum arabic solution (Baumé degree of 14) and 50 parts of propylene glycol was prepared.

Next, 10 parts of PELEX OFP (produced by Kao Corporation; sodium dialkylsulfo succinate), 15 parts of EMULGEN #703 (trade name, produced by Kao Corporation; polyoxyethylene nonyl phenyl ether), 10 parts of SPAN-20 (produced by Kao Corporation; sorbitan monolaurate), and 10 parts of ethylene glycol monobutyl ether, which are surfactants, were mixed into an oil phase consisting of 180 parts of SOLVENT No. 3 (trade name, produced by Nippon Oil Corporation; hydrocarbon solvent having a boiling point of 255° C.-287° C.).

The aqueous phase was stirred and adjusted to about 35 to 40° C. The oil phase (a mixture of the organic solvent and the surfactants) was slowly dropped thereinto to produce a dispersion, which was then passed through a homogenizer, thereby obtaining a milky-white, viscous emulsion cleaner 4.

### Example 5

The printing plate of Example 5 was obtained in the same manner as in Example 1 except that an emulsion cleaner 5 described below was used in place of the emulsion cleaner 1 used in “2. Washing and drying of printing surface” of Example 1.

Emulsion Cleaner 5

First, 495 parts by mass of purified water, 80 parts by mass of gum arabic (Grade HP type), 30 parts by mass of sodium hexametaphosphate, 20 parts by mass of magnesium nitrate, 5 parts by mass of sodium hydrogen sulfate, 15 parts by mass of phosphoric acid (85%), 50 parts by mass of glycerol (wetting agent) and 2.0 parts by mass of 4-isothiazolin-3-on derivative (preservative) were mixed to prepare an aqueous phase.

Then, 20 parts of PELEX OT-P (produced by Kao Corporation; sodium dialkylsulfo succinate), 10 parts of EMULGEN 105 (trade name, produced by Kao Corporation; polyoxyethylene lauryl ether) and 5 parts of NONION OP-80 (trade name, produced by NOF Corporation; sorbitan monooleate), which are surfactants, were dissolved into an oil phase consisting of 250 parts of squalane (produced by Nikko Chemicals Co., Ltd.).

The thus-prepared aqueous phase was heated with stirring and adjusted to 35° C. The oil phase was slowly dropped thereinto to produce a dispersion, which was then passed through a homogenizer, thereby obtaining a milky-white emulsion cleaner 5.

### Example 6

The printing plate of Example 6 was obtained in the same manner as in Example 1 except that an emulsion cleaner 6 described below was used in place of the emulsion cleaner 1 used in “2. Washing and drying of printing surface” of Example 1.

Emulsion Cleaner 6

First, 595 parts by mass of purified water, 80 parts by mass of water-soluble soybean polysaccharides (produced by Fuji Oil Co., Ltd.; trade name SOYAFIVE-S-LN: Chemical Analysis: galactose 43.6%, arabinose 22.5%, galacturonic acid 2.2%, remaining proteins 4.7%), 30 parts by mass of sodium hexametaphosphate, 20 parts by mass of magnesium nitrate, 5 parts by mass of sodium hydrogen sulfate, 15 parts by mass of phosphoric acid (85%), 50 parts by mass of glycerol (wetting agent) and 2.0 parts by mass of 4-isothiazolin-3-on derivative (preservative) were mixed to prepare an aqueous phase.

Then, 20 parts of PELEX OT-P (produced by Kao Corporation; sodium dialkylsulfo succinate), 10 parts of EMULGEN #903 (produced by Kao Corporation; polyoxyethylene nonyl phenyl ether) and 5 parts of NONION OP-80 (produced by NOF Corporation; sorbitan monooleate), which are surfactants, were dissolved into an oil phase consisting of 150 parts of SOLVENT-K (produced by Nippon Petrochemicals Co., Ltd.; hydrocarbon solvent having a boiling point of 151-190° C.).

The thus-prepared aqueous phase was heated with stirring and adjusted to 35° C. The oil phase was slowly dropped thereinto to produce a dispersion, which was then passed through a homogenizer, thereby obtaining a milky-white emulsion cleaner 6.

### Example 7

The printing plate of Example 7 was obtained in the same manner as in Example 1 except that an emulsion cleaner 7 described below was used in place of the emulsion cleaner 1 used in “2. Washing and drying of printing surface” of Example 1.

Emulsion Cleaner 7

First, 580 parts by mass of purified water, 60 parts by mass of water-soluble soybean polysaccharides (Chemical Analysis: galactose 43.6%, arabinose 22.5%, galacturonic acid 2.2%, remaining proteins 4.7%), 30 parts by mass of sodium silicate No. 3 (40%), 10 parts by mass of potassium pyrophosphate, 5 parts by mass of sodium hydroxide and 70 parts by mass of propylene glycol were mixed to prepare an aqueous phase.

Into an oil phase consisting of 180 parts by mass of SHELLSOL#71 (produced by Shell Sekiyu K. K.; hydrocarbon solvent having a boiling point of 170-207° C.) and 5 parts by mass of benzyl alcohol, 25 parts by mass of polyethylene glycol nonylphenyl ether (produced by Dai-ichi Kogyo Seiyaku Co., Ltd.; NOIGEN EA80), 15 parts by mass of sodium dialkylsulfo succinate (produced by NOF Corporation; RAPISOL B-80) and 20 parts by mass of sorbitan monolaurate (produced by Atlas; SPAN-40), which are surfactants, were dissolved.

The thus-prepared aqueous phase was heated with stirring and adjusted to 35° C. The oil phase was slowly dropped thereinto to produce a dispersion, which was then passed through a homogenizer, thereby obtaining a milky-white emulsion cleaner 7.

### Examples 8-16

The printing plates of Examples 8-16 were obtained in the same manner as in Example 1 except that the emulsion cleaners 8-16 described below were used, respectively, in place of the emulsion cleaner 1 used in “2. Washing and drying of printing surface” of Example 1.

Emulsion Cleaners 8-16

Into 450 parts by mass of purified water, 50 parts by mass of water-soluble soybean polysaccharides (produced by Fuji Oil Co., Ltd.; trade name SOYAFIVE-S-LN; Chemical Analysis: galactose 43.6%, arabinose 22.5%, galacturonic acid 2.2%, remaining proteins 4.7%) were dissolved. The acid components shown in Table 1 were added thereto at respective amounts shown in Table 1 and dissolved with stirring. Added sequentially thereto were 20 parts by mass of magnesium nitrate and 5 parts by mass of sodium hydrogen sulfate. Further, 5 parts by mass of 1,2-benzisothiazolin-3-one as a preservative and 40 parts by mass of glycerol as a wetting agent were mixed thereinto. Into the thus-obtained mixture, sodium hydroxide or citric acid was added to adjust the pH to 3.0, and water was then added thereto to a total of 650 parts by mass, thereby preparing an aqueous phase.

Meanwhile, 20 parts by mass of PELEX OT-P (produced by Kao Corporation; sodium dialkylsulfo succinate), 10 parts by mass of PIONIN D-212 (produced by Takemoto Oil & Fat Co., Ltd; castor oil ether) and 5 parts of NONION OP-80 (produced by NOF Corporation; sorbitan monooleate), which are emulsifiers, were dissolved into the organic solvent shown in Table 1 (in an amount shown in Table 1) to prepare an oil phase to a total of 350 parts.

Then, the thus-obtained aqueous phase was heated with stirring and adjusted to 35° C. The oil phase was slowly dropped thereinto to produce a dispersion, which was then passed through a homogenizer, thereby obtaining milky-white emulsion cleaners 8-16.

TABLE 1

| | | Emulsion Cleaner | | | | | | | | |
|---|---|---|---|---|---|---|---|---|---|---|
| | | 8 | 9 | 10 | 11 | 12 | 13 | 14 | 15 | 16 |
| Acid | Phosphoric acid (85%) | — | 20 | — | — | 20 | 20 | — | — | — |
| Component | Sodium | — | — | 20 | — | — | — | — | 20 | — |
| | hexametaphosphate | | | | | | | | | |
| | Phytic acid (50%) | — | — | — | 20 | — | — | — | — | 20 |
| | Citric acid | 20 | — | — | — | — | — | 20 | — | — |
| Organic | D-limonene *1 | — | — | — | — | 315 | — | — | — | — |
| Solvent | Soybean oil *2 | — | — | — | — | — | 315 | — | — | — |
| | SWASOL #1000 *3 | 315 | 315 | — | — | — | — | — | — | — |
| | EXXSOL D-80 *4 | — | — | 315 | 315 | — | — | 315 | 315 | 315 |

(Unit: parts by mass)
*1: monoterpene hydrocarbon; produced by Yasuhara Chemical Co., Ltd.
*2: fatty acid triglyceride; produced by Wako Pure Chemical Industries, Ltd.
*3: aromatic hydrocarbon; produced by Maruzen Petrochemical Co., Ltd.
*4: aliphatic hydrocarbon: produced by Exxon Chemicals

### Example 17

The printing plate of Example 17 was obtained in the same manner as in Example 1 except that an emulsion cleaner 17 described below (produced by Fujifilm Corporation; trade name: MULTICLEANER (MC-E)) was used in place of the emulsion cleaner 1 used in “2. Washing and drying of printing surface” of Example 1.

| | |
|---|---|
| Oil phase: | |
| Mineral spirit (CAS No. 64742-94-5; SP value: 7.8) | 16-26 wt % |
| Naphthalene (CAS No. 91-20-3; SP value: 8.6) | 0.1-1 wt % |
| Aqueous phase: | |
| Water | 50-70 wt % |
| Hemicellulose | 5-10 wt % |
| Monosodium phosphate | 1-5 wt % |
| Sodium hexametaphosphate | 1-5 wt % |
| Phosphoric acid | 1-5 wt % |
| Ammonium nitrate | 0.1-1 wt % |
| Surfactant | |
| Nonion Surfactant (CAS No. 61791-12-6; HLB value: 6) | 1-5 wt % |

### Example 18

The printing plate of Example 18 was obtained in the same manner as in Example 1 except that a laser recorder in which SCT200-808-Z6-01 (produced by ProLiteR; wavelength of 808 nm) was replaced with FC-LD in “1. Engraving” of Example 1 was used for laser-engraving.

Raster engraving was performed using this semiconductor laser engraving apparatus under the conditions of a laser output of 6 W, a head speed of 100 mm/s, and a pitch setting of 2,400 DPI, thereby forming a solid area of 1 cm×1 cm.

Here, this semiconductor laser engraving apparatus was represented by “LD” in the column of “Laser for Engraving” in Table 2.

### Example 19

The printing plate of Example 19 was obtained in the same manner as in Example 1 except that the below-described carbon dioxide laser engraving apparatus was used for laser-engraving in place of the semiconductor laser engraving apparatus used in “1. Engraving” of Example 1.

Raster engraving was performed using a high-grade CO₂ Laser Marker ML-9100 Series (manufactured by KEYENCE), as the carbon dioxide laser engraving apparatus, under the conditions of a laser output of 12 W, a head speed of 200 mm/s, and a pitch setting of 2,400 DPI, thereby forming a solid area of 1 cm×1 cm.

Here, this carbon dioxide laser engraving apparatus was represented by “CO₂” in the column of “Laser for Engraving” in Table 2.

### Example 20

The printing plate of Example 20 was obtained in the same manner as in Example 1 except that the coating liquid 2 for a relief forming layer which was obtained as described below was used in place of the coating liquid 1 for a relief forming layer used in “Preparation of Printing Plate Precursor” of Example 1.

In a three-necked flask equipped with a stirring blade and a condenser tube, 40 parts of a polyamide resin (Ultramid IC, manufactured by BASF; Tg is shown in Table 2) as the binder polymer, 10 parts by mass of diethylene glycol as the plasticizer, and 40 parts by mass of ethanol as the solvent were placed and heated at 70° C. for 120 minutes with stirring to dissolve the binder polymer.

Then, to this polymer solution, 20 parts by mass of an ethylenically-unsaturated monomer “LIGHT ACRYLATE” 14EG-A (trade name, diacrylate of polyethylene glycol 600 manufactured by Kyoeisha Chemical Co., Ltd.), 1.5 parts by mass of PERBUTYL Z (registered trademark; t-butyl peroxyoxide, manufactured by NOF Corporation) as the polymerization initiator, and as the polymerization inhibitors, 0.005 parts by mass of “Q-1300” (trade name; N-nitrosophenylhydroxylamine ammonium manufactured by Wako Pure Chemical Industries, Ltd.), 3 parts by mass of ZnCl₂ (manufactured by Wako Pure Chemical Industries, Ltd.) and 0.7 parts by mass of carbon black (trade name: SEAST 9H SAF-HS, manufactured by Tokai Carbon Co., Ltd.) were added. The resultant mixture was stirred for 30 minutes, thereby obtaining a fluid coating liquid 2 for a relief forming layer.

### Example 21

The printing plate of Example 21 was obtained in the same manner as in Example 1 except that the coating liquid 3 for a relief forming layer which was obtained as described below was used in place of the coating liquid 1 for a relief forming layer in “Preparation of Printing Plate Precursor” of Example 1.

### Synthesis Example

### Synthesis of Polyurethane Resin P-1

In a 500 ml three-necked flask equipped with a condenser and stirrer, 8.2 g (0.05 mol) of 2,2-bis(hydroxymethyl)butanoic acid and 13.0 g (0.05 mol) of the below-described diol compound (I) were dissolved into 100 ml of N,N-dimethylacetamide. Added thereto were 25.5 g (0.102 mol) of 4,4-diphenylmethane diisocyanate and 0.1 g of dibutyl tin dilaurylate, and the resultant mixture was heated with stirring at 100° C. for 8 hours. Subsequently, the resultant product was diluted with 100 ml of N,N-dimethylformamide and 200 ml of methylalcohol, and stirred for 30 minutes. The reaction solution was poured into 3 liters of water with stirring to allow a white polymer to precipitate. The thus-obtained polymer was removed by filtration and washed with water, followed by vacuum drying, thereby obtaining 37 g of a polyurethane resin P-1.

The molecular weight of the polyurethane resin P-1 was measured by gel permeation chromatography (GPC), and the weight-average molecular weight (polystyrene standard) thereof was found to be 95,000.

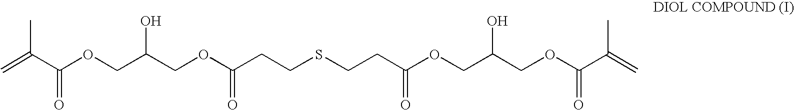

Preparation of Coating Liquid 3 for Relief Forming Layer

First, 50 parts by mass of the polyurethane resin P-1 (Tg thereof is shown in Table 2) obtained as described above was mixed with 0.8 parts by mass of carbon black ASAHI #55 (N-660) (trade name, manufactured by Asahi Carbon Co., Ltd.) as the photothermal converting agent and 22.6 parts by mass of dioctyl phthalate as the plasticizer. Furthermore, 25 parts by mass of lauryl acrylate as the polymerizable compound and 1.6 parts by mass of IRGACURE 369 (trade name, manufactured by Ciba-Geigy Corporation) as the polymerization initiator were mixed thereto. The resultant mixture was dissolved in toluene at 100° C. and then cooled to 40° C., thereby obtaining a coating liquid 3 for a relief forming layer.

### Example 22

The printing plate of Example 22 was obtained in the same manner as in Example 1 except that a coating liquid 4 for a relief forming layer which was obtained as described below was used in place of the coating liquid 1 for a relief forming layer used in “Preparation of Printing Plate Precursor” of Example 1.

In a three-necked flask equipped with a stirring blade and a condenser tube, 52.5 parts by mass of poly(methyl methacrylate) (Mw15000; manufactured by Kanto Chemical Co., Inc.) as the binder polymer, 17.5 parts by mass of diethyl phthalate (produced by Kanto Chemical Co., Inc.) as the plasticizer and 30 parts by mass of tetrahydrofuran (THF) as the solvent were placed and heated at 80° C. for 48 hours with stirring to dissolve the binder polymer. Further, the resultant was heated at 120° C. for 2 hours with stirring to completely dissolve the binder polymer.

Further added to the thus-obtained polymer solution were 15 parts by mass of an ethylenically-unsaturated monomer “LIGHT ACRYLATE” 14EG-A (trade name, diacrylate of polyethylene glycol 600 manufactured by Kyoeisha Chemical Co., Ltd.) as a polymerizable compound, 15 parts by mass of a polyalkylene glycol (meth)acrylate monomer “BLEMMER PE-200” (trade name, produced by NOF Corporation) as a polymerizable compound, 1.5 parts by mass of PERBUTYL Z (registered trademark; t-butyl peroxyoxide manufactured by NOF Corporation) as the polymerization initiator, and as the polymerization inhibitors, 0.005 parts by mass of “Q-1300” (trade name; N-nitrosophenylhydroxylamine ammonium manufactured by Wako Pure Chemical Industries, Ltd.), 3 parts by mass of ZnCl₂ (manufactured by Wako Pure Chemical Industries, Ltd.) and 0.7 parts by mass of carbon black (trade name: SEAST 9H SAF-HS, manufactured by Tokai Carbon Co., Ltd.). The resultant was stirred for 30 minutes, thereby obtaining a fluid coating liquid 4 for a relief forming layer.

The Tg of poly(methyl methacrylate) under a condition in which the plasticizer coexisted therewith was measured to be 38° C. Further, the Tg of poly(methyl methacrylate) under a condition in which the plasticizer was not added was measured to be 104° C.

### Example 23

The printing plate of Example 23 was obtained in the same manner as in Example 1 except that a coating liquid 4 for a relief forming layer which was obtained as described below was used in place of the coating liquid 1 for a relief forming layer used in “Preparation of Printing Plate Precursor” of Example 1.

In a three-necked flask equipped with a stirring blade and a condenser tube, 52.5 parts by mass of polystyrene beads (Kanto Chemical Co., Inc.) as the binder polymer, 17.5 parts by mass of diethylbenzene (Kanto Chemical Co., Inc.) as the plasticizer and 30 parts by mass of tetrahydrofuran (THF) as the solvent were placed and heated at 80° C. for 48 hours with stirring to dissolve the binder polymer. Further, the resultant was heated at 120° C. for 2 hours with stirring to completely dissolve the binder polymer.

Further added to the thus-obtained polymer solution were 15 parts by mass of an ethylenically-unsaturated monomer “LIGHT ACRYLATE” 14EG-A (trade name, diacrylate of polyethylene glycol 600 produced by Kyoeisha Chemical Co., Ltd.) as a polymerizable compound, 15 parts by mass of a polyalkylene glycol (meth)acrylate monomer “BLEMMER PE-200” (trade name, manufactured by NOF Corporation) as a polymerizable compound, 1.5 parts by mass of PERBUTYL Z (registered trademark; t-butyl peroxyoxide manufactured by NOF Corporation) as the polymerization initiator, and as the polymerization inhibitors, 0.005 parts by mass of “Q-1300” (trade name; N-nitrosophenylhydroxylamine ammonium manufactured by Wako Pure Chemical Industries, Ltd.), 3 parts by mass of ZnCl₂ (manufactured by Wako Pure Chemical Industries, Ltd.) and 0.7 parts by mass of carbon black (trade name: SEAST 9H SAF-HS, manufactured by Tokai Carbon Co., Ltd.). The resultant was stirred for 30 minutes, thereby obtaining a fluid coating liquid 5 for a relief forming layer.

The Tg of polystyrene under a condition in which the plasticizer coexisted therewith was measured to be 5° C. Further, the Tg of polystyrene under a condition in which the plasticizer was not added was measured to be 100° C.

### Example 25

The printing plate of Example 25 was obtained in the same manner as in Example 8 except that “trade name: TITAN BLACK (particle diameter of 1 μm or less), model number: 13M; produced by Mitsubishi Materials Corporation or JEMCO” was used in place of “carbon black” in the coating liquid 1 for a relief forming layer used in Example 8.

### Example 26

The printing plate of Example 26 was obtained in the same manner as in Example 1 except that a coating liquid 6 for a relief forming layer which was obtained as described below was used in place of the coating liquid 1 for a relief forming layer in “Preparation of Printing Plate Precursor” of Example 1.

In a three-necked flask equipped with a stirring blade and a condenser tube, 52.5 parts by mass of PET resin beads (manufactured by Mitsubishi Materials Corporation or JEMCO) containing carbon nanofibers as the binder polymer, 17.5 parts by mass of diethylbenzene (manufactured by Kanto Chemical Co., Inc.) as the plasticizer and 30 parts by mass of ethanol as the solvent were placed and heated at 80° C. for 48 hours with stirring to dissolve the binder polymer. Further, the resultant was heated at 120° C. for 2 hours with stirring to completely dissolve the binder polymer.

Further added to the thus-obtained polymer solution were 15 parts by mass of an ethylenically-unsaturated monomer “LIGHT ACRYLATE” 14EG-A (trade name; diacrylate of polyethylene glycol 600 manufactured by Kyoeisha Chemical Co., Ltd.) as a polymerizable compound, 15 parts by mass of a polyalkylene glycol (meth)acrylate monomer “BLEMMER PE-200” (trade name, manufactured by NOF Corporation) as a polymerizable compound, 1.5 parts by mass of PERBUTYL Z (registered trademark; t-butyl peroxyoxide manufactured by NOF Corporation) as the polymerization initiator, and as the polymerization inhibitors, 0.005 parts by mass of “Q-1300” (trade name; N-nitrosophenylhydroxylamine ammonium manufactured by Wako Pure Chemical Industries, Ltd.) and 3 parts by mass of ZnCl₂ (manufactured by Wako Pure Chemical Industries Ltd.). The resultant was stirred for 30 minutes, thereby obtaining a fluid coating liquid 6 for a relief forming layer.

The Tg of polyethylene terephthalate under a condition in which the plasticizer coexisted therewith was measured to be −2° C. Further, the Tg of polyethylene terephthalate under a condition in which the plasticizer was not added was measured to be 70° C.

### Comparative Example 1

The printing plate of Comparative Example 1 was obtained in the same manner as in Example 8 except that the washing and drying were carried out in the manner described below, instead of those in “2. Washing and drying of printing surface” of Example 8.

A laser-engraved, unwashed printing plate was washed for 5 minutes with circulating water (tap water) using a brush washer (trade name: WASHERMAN; manufactured by Kamitani Co., Ltd.), followed by drying with spraying of compressed air thereto.

### Comparative Example 2

The printing plate of Comparative Example 2 was obtained in the same manner as in Example 8 except that the method of washing using the below-described water was used in place of the method of washing in “2. Washing and drying of printing surface” of Example 8.

A laser-engraved, unwashed printing plate was washed using a high-temperature high-pressure washing machine (produced by Karcher; trade name “HDS 795”). Here, the temperature of high-temperature steam was 107° C., and the pressure was 5 MPa. Further, the distance between the laser-engraved printing plate and the nozzle from which the high-pressure steam was ejected was set at 0.15 m.

### Comparative Example 3

The printing plate of Comparative Example 3 was obtained in the same manner as in Example 1 except that a coating liquid 7 for a relief forming layer which was obtained as described below was used in place of the coating liquid 1 for a relief forming layer used in “Preparation of Printing Plate Precursor” of Example 1.

In a three-necked flask equipped with a stirring blade and a condenser tube, 50 parts by mass of a styrene-butadiene polymer (trade name: NIPOL NS 116R; manufactured by Zeon Corporation; Tg thereof is shown in Table 2) as the binder polymer, 0.7 parts by mass of carbon black (trade name: SEAST 9H SAF-HS, manufactured by Tokai Carbon Co., Ltd.) and 30 parts by mass of methyl ethyl ketone were placed and stirred for 30 minutes, thereby obtaining a fluid coating liquid 7 for a relief forming layer.

A laser-engraved, unwashed printing plate was washed for 5 minutes with circulating water (tap water) using a brush washer (trade name: WASHERMAN; produced by Kamitani Co., Ltd.), followed by drying with spraying of compressed air thereto.

Evaluation

Also for Examples 2-25 and Comparative Examples 1-3, the evaluations were carried out on “1. Observation of engraving residue in grooves using optical microscope” as well as on “2. Width of engraved thin line” in the same manners as in Example 1. The results are shown in Table 2.

TABLE 2

| | Binder | | | | | Observation | Minimum width of |
|---|---|---|---|---|---|---|---|
| | polymer | | photothermal | Laser for | | of engraving | negative thin line |
| | Type | Tg [° C.] | converting agent | engraving | Cleaner | residue | [μm] |
| Example 1 | PVB | 68 | CB | FC-LD | 1 | A | 30 |
| Example 2 | PVB | 68 | CB | FC-LD | 2 | A | 30 |
| Example 3 | PVB | 68 | CB | FC-LD | 3 | A | 30 |
| Example 4 | PVB | 68 | CB | FC-LD | 4 | A | 30 |
| Example 5 | PVB | 68 | CB | FC-LD | 5 | A | 30 |
| Example 6 | PVB | 68 | CB | FC-LD | 6 | A | 30 |
| Example 7 | PVB | 68 | CB | FC-LD | 7 | A | 30 |
| Example 8 | PVB | 68 | CB | FC-LD | 8 | A | 30 |
| Example 9 | PVB | 68 | CB | FC-LD | 9 | A | 30 |
| Example 10 | PVB | 68 | CB | FC-LD | 10 | A | 30 |
| Example 11 | PVB | 68 | CB | FC-LD | 11 | A | 30 |
| Example 12 | PVB | 68 | CB | FC-LD | 12 | A | 30 |
| Example 13 | PVB | 68 | CB | FC-LD | 13 | A | 30 |
| Example 14 | PVB | 68 | CB | FC-LD | 14 | A | 30 |
| Example 15 | PVB | 68 | CB | FC-LD | 15 | A | 30 |
| Example 16 | PVB | 68 | CB | FC-LD | 16 | A | 30 |
| Example 17 | PVB | 68 | CB | FC-LD | 17 | A | 30 |
| Example 18 | PVB | 68 | CB | LD | 8 | B | 50 |
| Example 19 | PVB | 68 | CB | CO₂ | 8 | B | 50 |
| Example 20 | polyamide | 315 | CB | FC-LD | 8 | A | 30 |
| Example 21 | poly-urethane | 110 | CB | FC-LD | 8 | A | 30 |
| Example 22 | PMMA | 104 | CB | FC-LD | 8 | A | 30 |
| Example 23 | PS | 100 | CB | FC-LD | 8 | A | 30 |
| Example 24 | PVB | 68 | TITAN BLACK | FC-LD | 8 | B | 30 |
| | | | (diameter: 1 μm) | | | | |
| Example 25 | PET | 70 | Carbon nanofiber | FC-LD | 8 | B | 30 |
| Comparative Example 1 | PVB | 68 | CB | FC-LD | water | C | 80 |
| Comparative Example 2 | PVB | 68 | CB | FC-LD | water (high-temperature, | C | 80 |
| | | | | | high-pressure) | | |
| Comparative Example 3 | SBR | −40 | CB | FC-LD | water | C | 100 |

As clearly shown in Table 2, when the method of making a printing plate (Examples of the present application) which includes a step of washing with an emulsion cleaner and in which a printing plate precursor having a relief forming layer containing a binder polymer having a glass transition temperature of 20° C. or higher is used, superior removability of engraving residue is obtained.

Further, it can be seen that the methods of making a printing plate of Examples of the present application enable a superior forming property of a thin line compared to that in Comparative Examples, as a finer thin line can be obtained.

As described above, it can be understood that the methods of making a printing plate in Examples enable the formation of a thin line and that, since no engraving residue that would cause a practical problem was observed on the plates, it would become easy to form a desired thin line, thereby achieving a superior reproducibility of the thin line.

What is claimed is:

1. A method of making a printing plate, comprising in the following order:
engraving by laser irradiation a relief forming layer of a printing plate precursor, the relief forming layer comprising a binder polymer having a glass transition temperature (Tg) of 20° C. or higher; and
treating a surface of the engraved relief forming layer with an emulsion cleaner.

2. The method of making a printing plate according to claim 1, wherein the glass transition temperature of the binder polymer is 25° C. or higher.

3. The method of making a printing plate according to claim 1, wherein the binder polymer comprises at least one selected from the group consisting of polystyrenes, polyesters, polyamides, polyureas, polyamide-imides, polyurethanes, polysulfones, polyether sulfones, polyimides, polycarbonates, hydrophilic polymers comprising a hydroxyethylene unit, (meth)acrylic resins, acetal resins, epoxy resins, synthetic rubbers, and thermoplastic elastomers.

4. The method of making a printing plate according to claim 1, wherein the binder polymer comprises a polymer which has a carbon-carbon unsaturated bond in a molecule thereof.

5. The method of making a printing plate according to claim 1, wherein the binder polymer comprises at least one of a polyvinyl alcohol or a derivative thereof.

6. The method of making a printing plate according to claim 1, wherein the total content of the binder polymer in the relief forming layer is from 15% by mass to 75% by mass with respect to the total solid content of the relief forming layer.

7. The method of making a printing plate according to claim 1, wherein the relief forming layer further comprises a photothermal converting agent.

8. The method of making a printing plate according to claim 7, wherein the photothermal converting agent comprises carbon black.

9. The method of making a printing plate according to claim 7, wherein the content of the photothermal converting agent is from 0.01% by mass to 20% by mass with respect to the total solid content of the relief forming layer.

10. The method of making a printing plate according to claim 1, wherein the relief forming layer further comprises a cross-linking agent.

11. The method of making a printing plate according to claim 1, wherein the laser irradiation is performed using a fiber-coupled semiconductor laser.

12. The method of making a printing plate according to claim 1, wherein the emulsion cleaner comprises an organic solvent which dissolves a thermal decomposition product of the binder polymer; at least one surfactant selected from the group consisting of anionic surfactants and nonionic surfactants; and water.

13. The method of making a printing plate according to claim 12, wherein the organic solvent comprises:
a petroleum hydrocarbon, an aromatic hydrocarbon, a monoterpene hydrocarbon, or a fatty acid triglyceride; or
a mixture comprising at least two selected from the group consisting of a petroleum hydrocarbon, an aromatic hydrocarbon, a monoterpene hydrocarbon, and a fatty acid triglyceride.

14. The method of making a printing plate according to claim 12, wherein the content of the organic solvent is from 3% by mass to 50% by mass with respect to the total mass of the emulsion cleaner.

15. The method of making a printing plate according to claim 1, which is a method of making a flexographic printing plate.
